(19) United States
(12) Patent Application Publication
(10) Pub. No.: US 2012/0175788 A1
(43) Pub. Date: Jul. 12, 2012

(54) SEMICONDUCTOR DEVICE, SEMICONDUCTOR PACKAGE, AND METHOD FOR MANUFACTURING SEMICONDUCTOR DEVICE

(75) Inventor: Takao OCHI, Shiga (JP)

(73) Assignee: PANASONIC CORPORATION, Osaka (JP)

(21) Appl. No.: 13/427,085

(22) Filed: Mar. 22, 2012

Related U.S. Application Data
(63) Continuation of application No. PCT/JP2010/004820, filed on Jul. 29, 2010.

(30) Foreign Application Priority Data
Sep. 24, 2009 (JP) 2009-219276

(51) Int. Cl. H01L 23/498

(52) U.S. Cl. 257/786; 257/E23.068

(57) ABSTRACT

The heat dissipation capability of a mounted semiconductor element can be improved, and the flexibility of circuit design of the semiconductor element and a circuit board and the productivity of the semiconductor element during a mounting step can be improved. A semiconductor element 1 and a circuit board 3 are arranged so that while the first main surfaces 1a and 3a of the semiconductor element 1 and the circuit board 3 face in the same direction and side surfaces 1c and 3c of the semiconductor element 1 and the circuit board 3 face each other, the connection electrode 2 and the electrode pad 4 are connected together. The first main surfaces 1a and 3a of the semiconductor element 1 and the circuit board 3 are covered with an encapsulation resin 7.

### TECHNICAL FIELD

The present invention relates to semiconductor devices in which semiconductor elements are mounted on a circuit board, semiconductor packages in which the semiconductor device is mounted on an external circuit board, and methods for manufacturing the semiconductor device.

### BACKGROUND ART

In recent years, as the functions of electronic apparatuses have advanced quickly, the power consumption of semiconductor elements used in the electronic apparatus has increased. Therefore, there is a demand for an improvement in the heat dissipation capability of a semiconductor device in which semiconductor elements are packaged on a circuit board.

In order to achieve an improvement in the heat dissipation capability of a semiconductor device in which semiconductor elements are mounted on a circuit board, the thickness of a portion of the circuit board where the semiconductor element is mounted may be reduced, or the semiconductor element may be provided in a through hole formed in the circuit board to expose and allow the bottom surface of the semiconductor element to contact directly a heat dissipator, such as a heat sink screw etc., for example (see Patent Document 1).

Alternatively, terminals connected to semiconductor elements via metal wires and the semiconductor elements may be integrated together using an encapsulation resin, whereby the heat dissipation characteristics of the semiconductor element are improved without using a circuit board (see Patent Document 2).

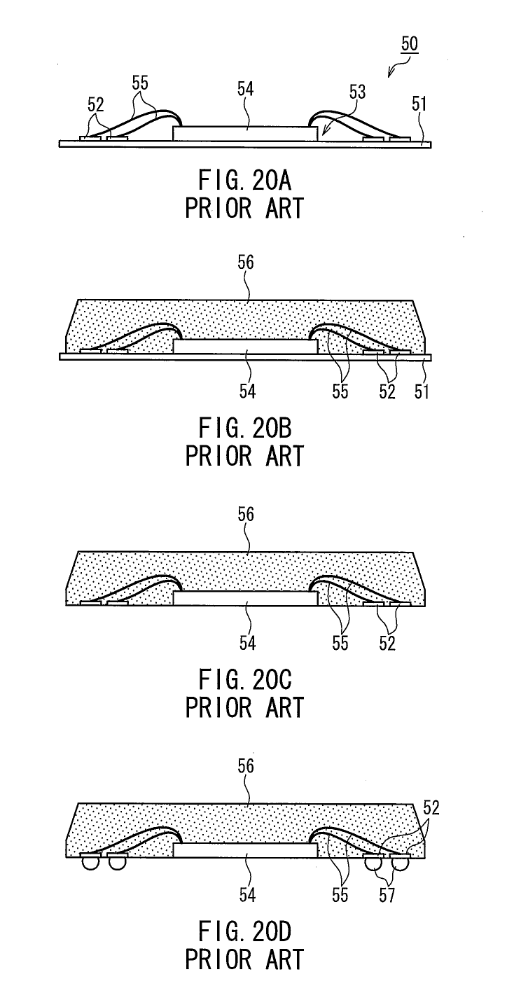

FIG. 20 shows a process for manufacturing a conventional semiconductor device that is described in Patent Document 2. In the process for manufacturing the conventional semiconductor device 50, initially, as shown in FIG. 20A, a semiconductor element 54 is firmly but detachably attached by an adhesive (not shown) to a semiconductor mount region 53 formed in a middle portion of a top surface of a flexible tape 51 on which a plurality of terminals 52 are formed. Thereafter, connection electrodes (not shown) of the semiconductor element 54 on the tape 51 are connected to the terminals 52 by wires 55. Next, as shown in FIG. 20B, the semiconductor element 54 and the terminals 52 on the top surface of the tape 51 and the wires 55 are covered with an insulating encapsulation resin 56. Thereafter, as shown in FIG. 20C, the tape 51 is removed. Finally, as shown in FIG. 20D, protruding electrodes 57 (solder balls etc.) for connecting to an external circuit board are formed on the exposed bottom surfaces of the terminals 52.

Thus, in the semiconductor device 50, the bottom surface of the semiconductor element 54 is exposed. Therefore, the heat dissipation capability of the semiconductor device 50 can be improved.

### CITATION LIST

### Patent Documents

Patent Document 1: JP 60-227452 A

Patent Document 2: JP 2003-303919 A

### DISCLOSURE OF INVENTION

### Problem to be Solved by the Invention

However, in both of the above conventional semiconductor devices (Patent Documents 1 and 2), only the bottom surface of a mounted semiconductor element, i.e., a second main surface that is opposite to a first main surface on which connection electrodes to be connected to electrode pads on the board or terminals on the tape are provided, is exposed. Therefore, the dissipation of heat from the semiconductor element is not sufficient.

Also, the exposed bottom surface of the semiconductor element, around which the circuit board and the terminals covered with the encapsulation resin, etc. are provided, is located at a middle portion of the entire semiconductor device. Therefore, when the semiconductor device is mounted on an external circuit board, such as a mother board etc., the bottom surface of the semiconductor element is unlikely to be exposed to the ambient atmosphere. Also, it would be difficult to attach heat dissipation means, such as a heat sink plate or a heat dissipation portion etc. Moreover, when a so-called underfill is formed between the external circuit board and the bottom surface of the semiconductor device, the perimeter of the bottom surface of the semiconductor element that is intended to be exposed is surrounded by the underfill, and therefore, the heat dissipation characteristics cannot be improved.

Also, the connection electrodes on the first main surface of the semiconductor element are connected to electrode pads on the circuit board or terminals on the tape that are provided around the connection electrodes, and therefore, there is a significant constraint on the design of a pattern of the semiconductor element itself and the design of interconnects on the circuit board. Moreover, because a region where the semiconductor element is mounted is formed in a middle of the board or the tape, the semiconductor element is mounted on the board or the tape on a one-by-one basis, and therefore, it is unavoidable that the productivity of the semiconductor device will decrease during the manufacturing process.

Thus, conventional semiconductor devices have the following problems. The heat dissipation capability of the semiconductor element cannot be sufficiently improved, resulting in low flexibility in terms of circuit design of the semiconductor element itself and the board connected to the semiconductor element, etc. Also, it is difficult to increase the productivity of the semiconductor element manufacturing process in which the semiconductor element is mounted.

The present invention provides a solution to the above conventional problems. It is an object of the present invention to provide a semiconductor device, semiconductor package, and semiconductor device manufacturing method in which the heat dissipation capability of a mounted semiconductor element can be improved, and the flexibility of circuit design of the semiconductor element and a circuit board and the productivity of a process of mounting the semiconductor element both can be improved.

### Means for Solving Problem

In order to achieve the object, in a semiconductor device of the present invention, a semiconductor element having a first main surface on which a connection electrode is formed, a second main surface opposite to the first main surface, and a plurality of side surfaces, and a circuit board having a first main surface on which an electrode pad is formed, a second main surface opposite to the first main surface, and a plurality of side surfaces, are arranged so that while the first main surfaces of the semiconductor element and the circuit board face in the same direction and the side surfaces of the semiconductor element and the circuit board face each other, the connection electrode and the electrode pad are connected together. The first main surfaces of the semiconductor element and the circuit board are covered with an encapsulation resin.

In a semiconductor package of the present invention, the semiconductor device of the present invention is mounted on an external circuit board, and the external electrode formed on the second main surface of the circuit board included in the semiconductor device is connected to a mounted electrode terminal formed on a mounting surface of the external circuit board on which the semiconductor device is mounted.

A semiconductor device manufacturing method of the present invention includes a placing step of placing, on a holding plate, a semiconductor element having a first main surface on which a connection electrode is formed, a second main surface opposite to the first main surface, and a plurality of side surfaces, and a circuit board having a first main surface on which an electrode pad is formed, a second main surface opposite to the first main surface, and a plurality of side surfaces, side by side with the first main surfaces of the semiconductor element and the circuit board facing in the same direction, a connecting step of connecting the connection electrode and the electrode pad together, an encapsulating step of covering the semiconductor element and the circuit board with an encapsulation resin, and a holding plate removing step of removing the holding plate.

### Effects of the Invention

In the semiconductor device of the present invention, all of the two main surfaces and the side surfaces of the semiconductor element other than the first main surface covered with the encapsulation resin can be exposed, whereby the heat dissipation capability of the mounted semiconductor element can be improved. Also, the semiconductor element and the circuit board are arranged side by side, whereby the flexibility of interconnect design of the semiconductor element and the circuit board and the productivity of the semiconductor element during a mounting step both can be improved.

Also, in the semiconductor package of the present invention, the semiconductor element and the circuit board are arranged side by side, whereby the heat dissipation capability of the semiconductor element can be improved.

Also, the semiconductor device manufacturing method of the present invention can be used to manufacture easily a semiconductor device in which the heat dissipation capability of a mounted semiconductor element can be improved, whereby the flexibility of circuit design of the semiconductor element and a circuit board and the productivity of the semiconductor element during a mounting step can be improved.

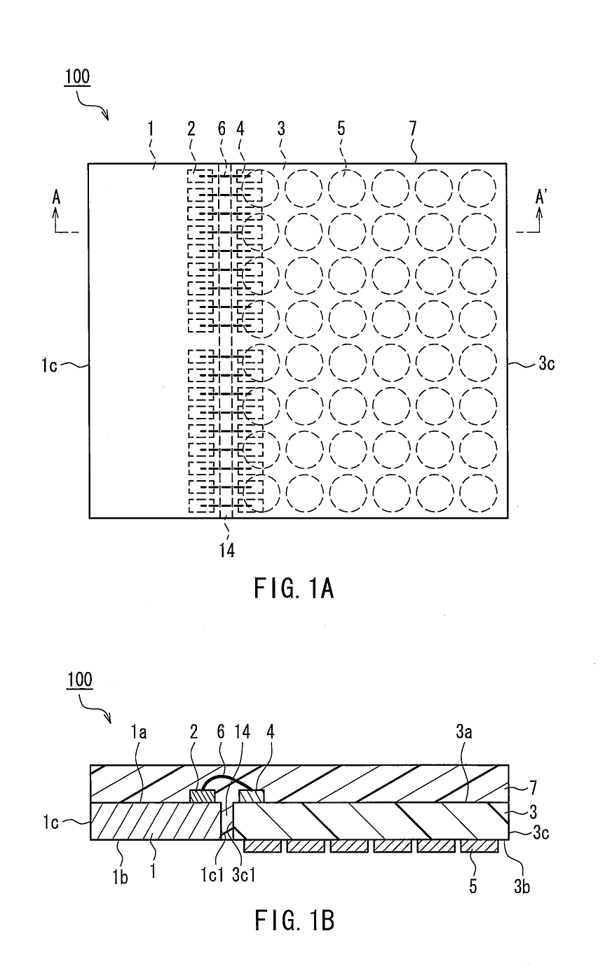

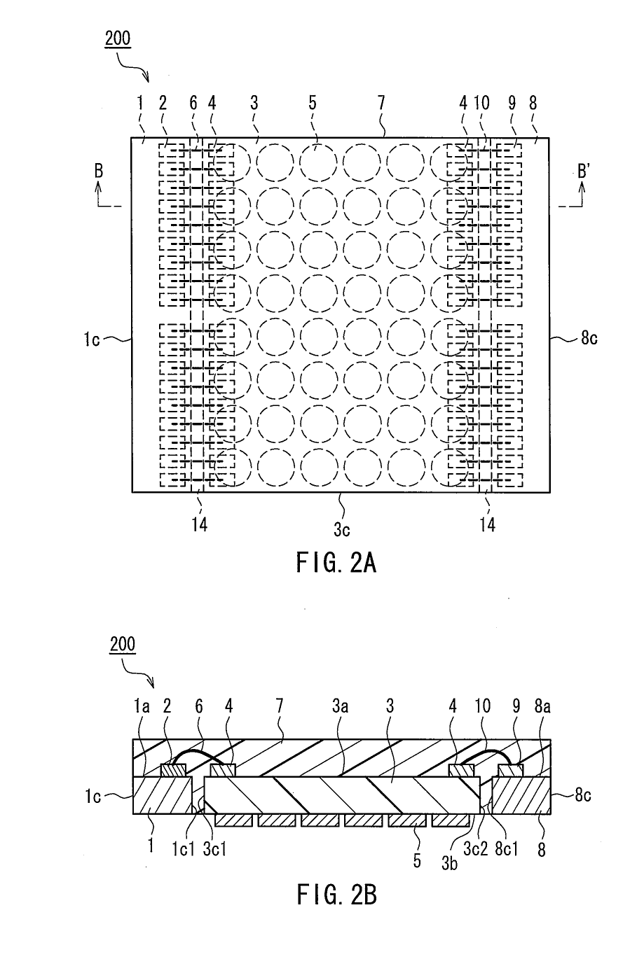

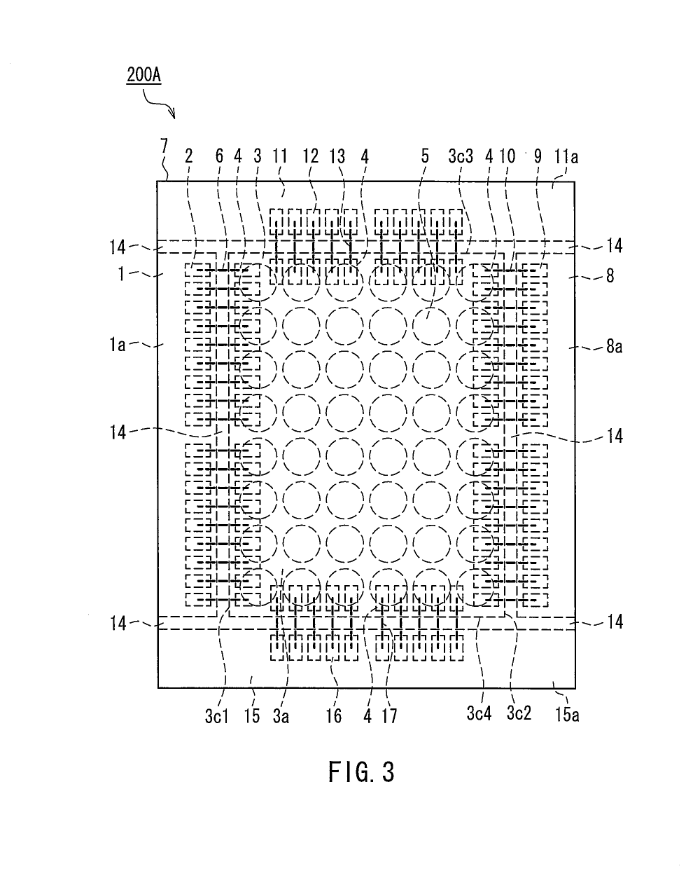

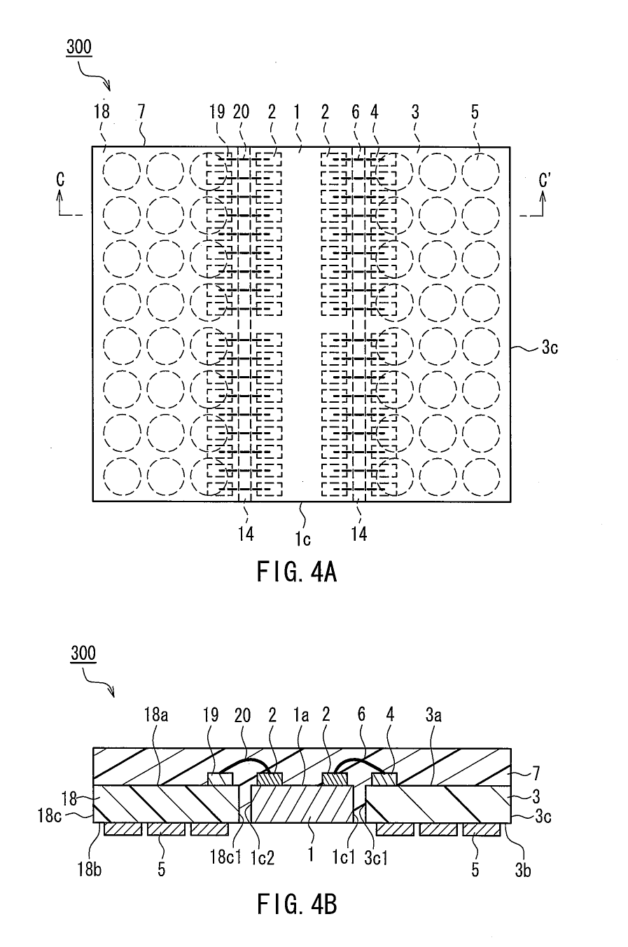

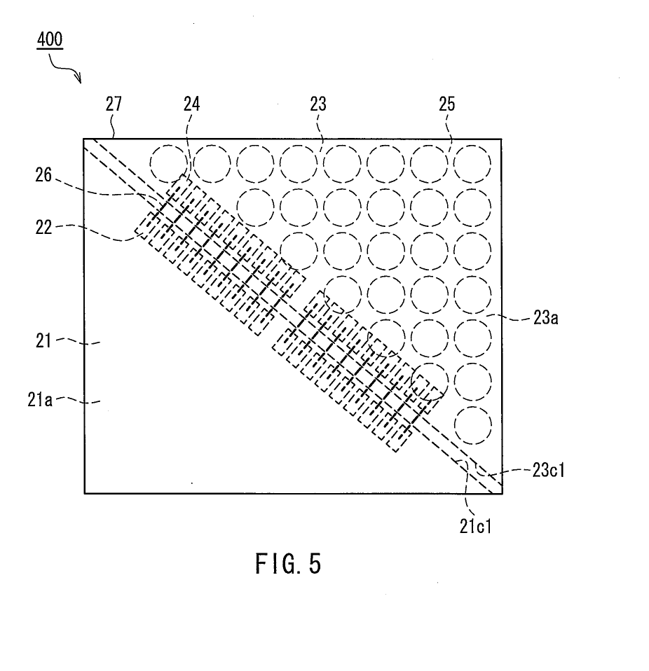

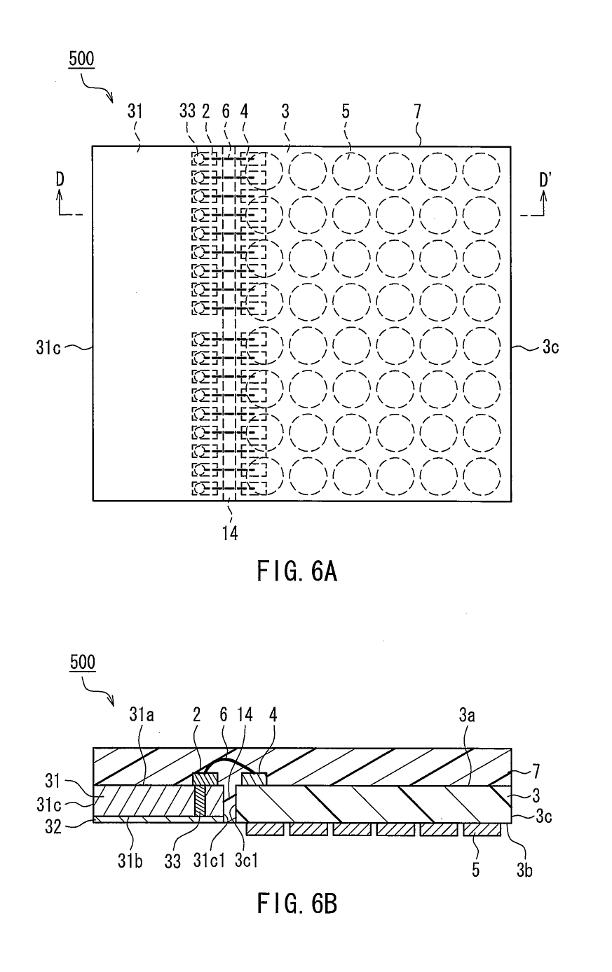

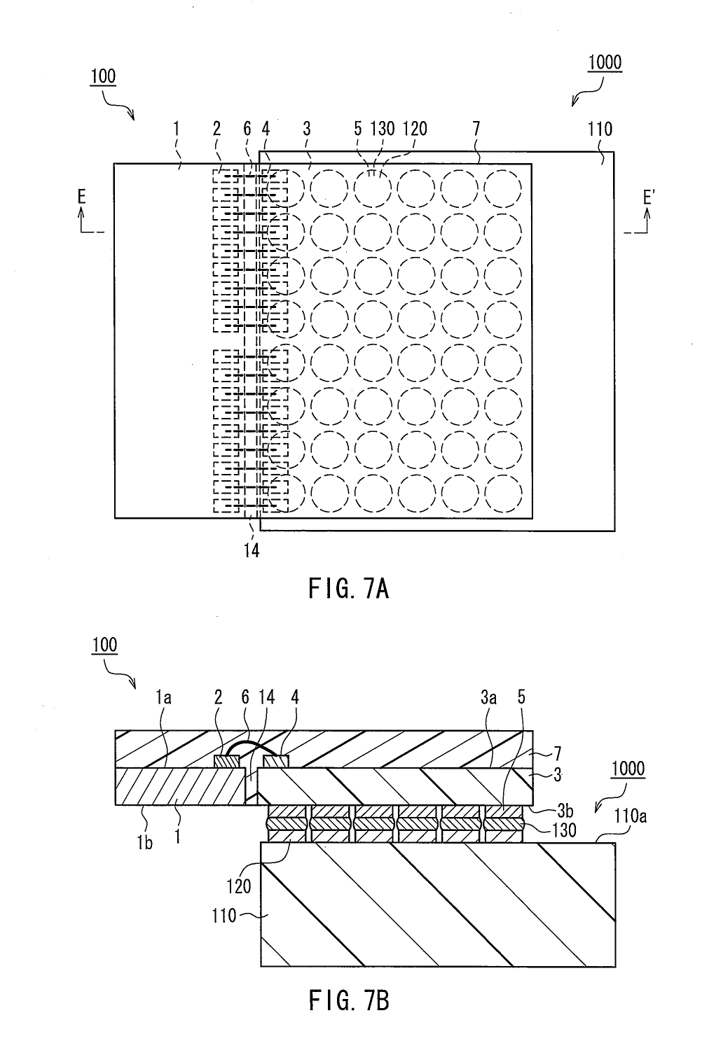

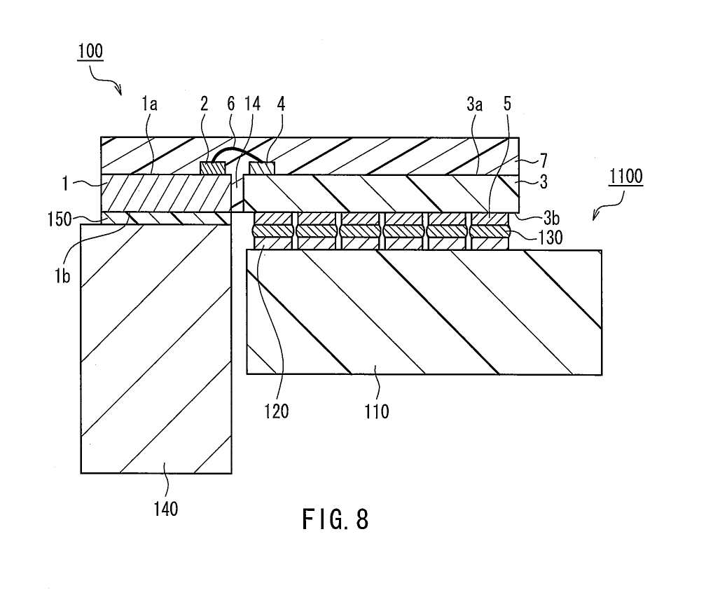

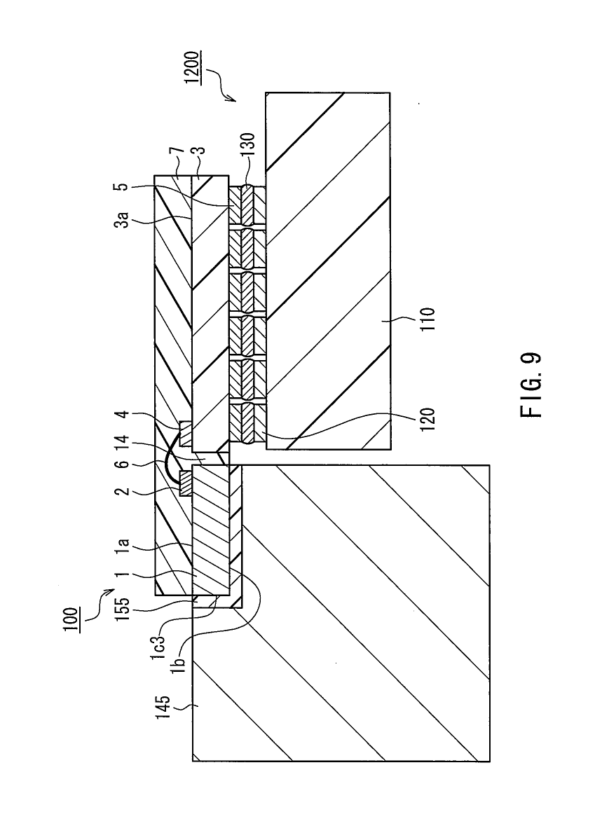

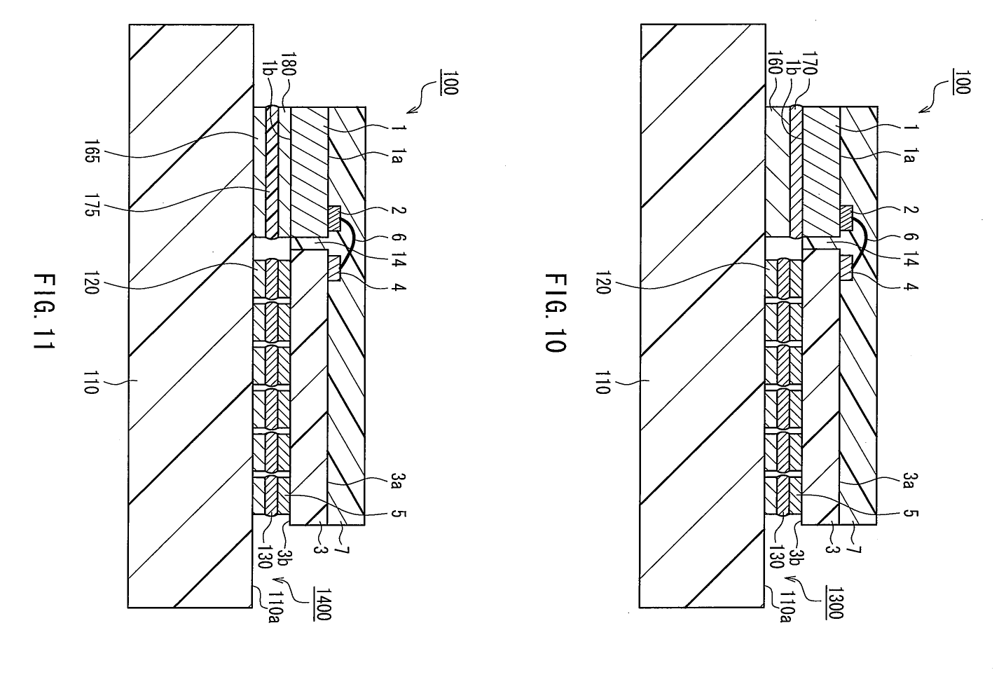

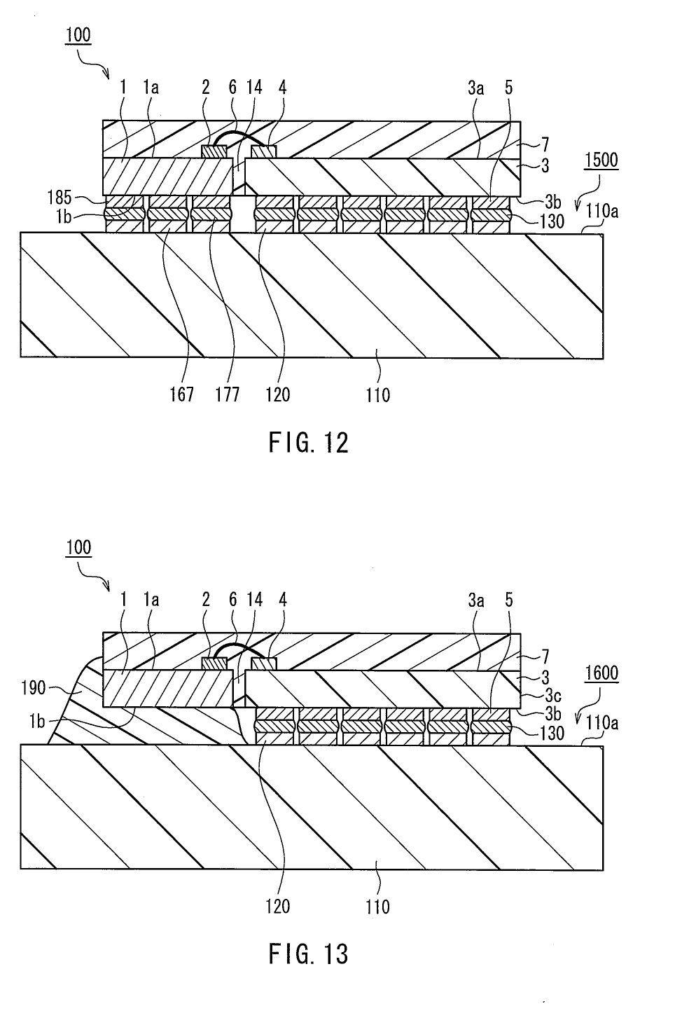

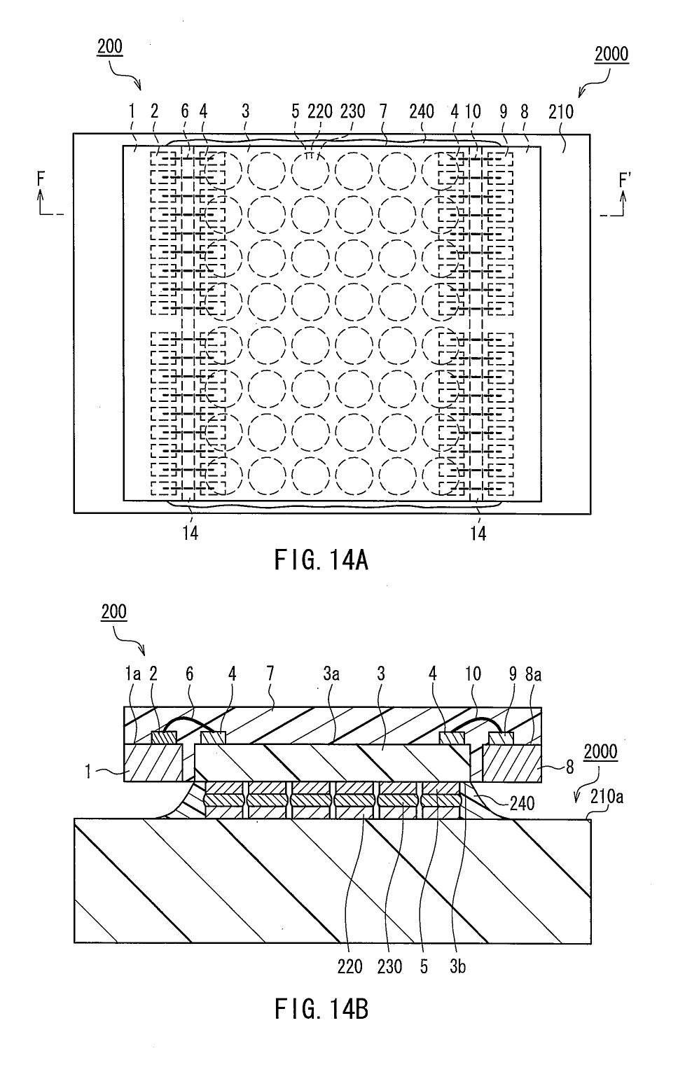

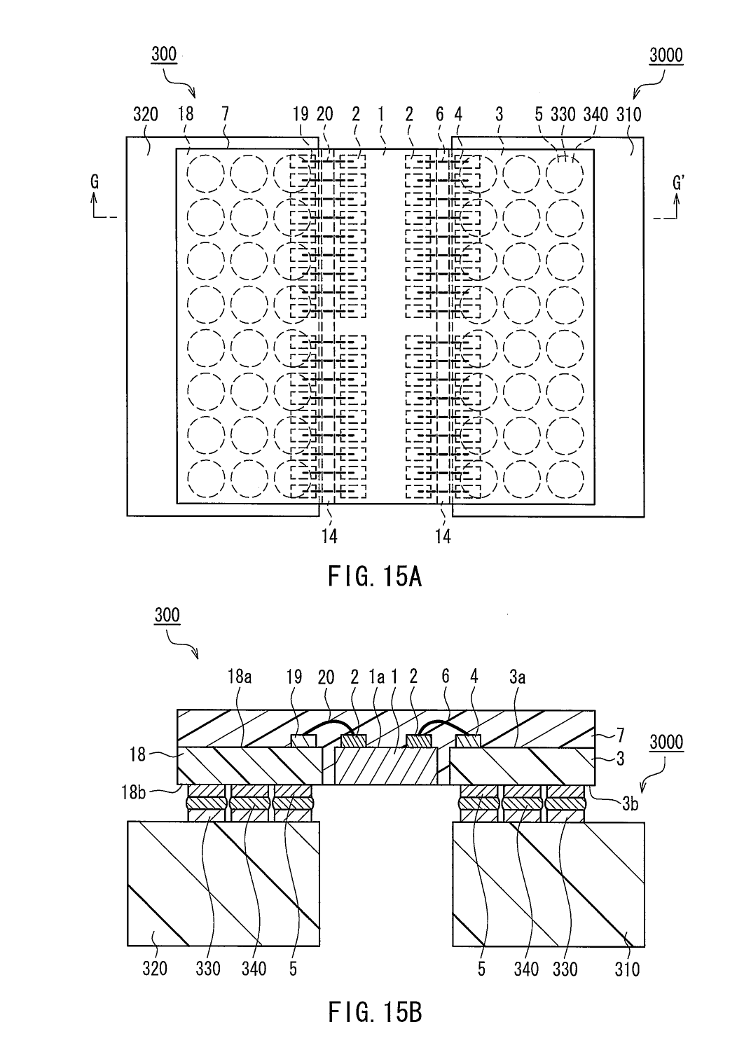

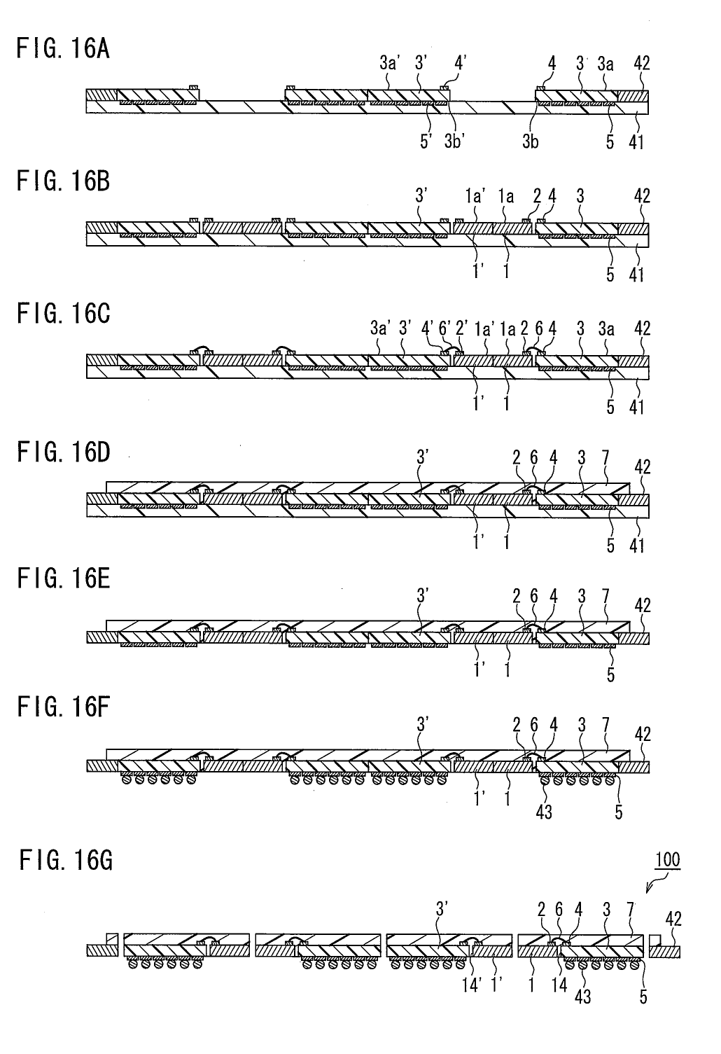

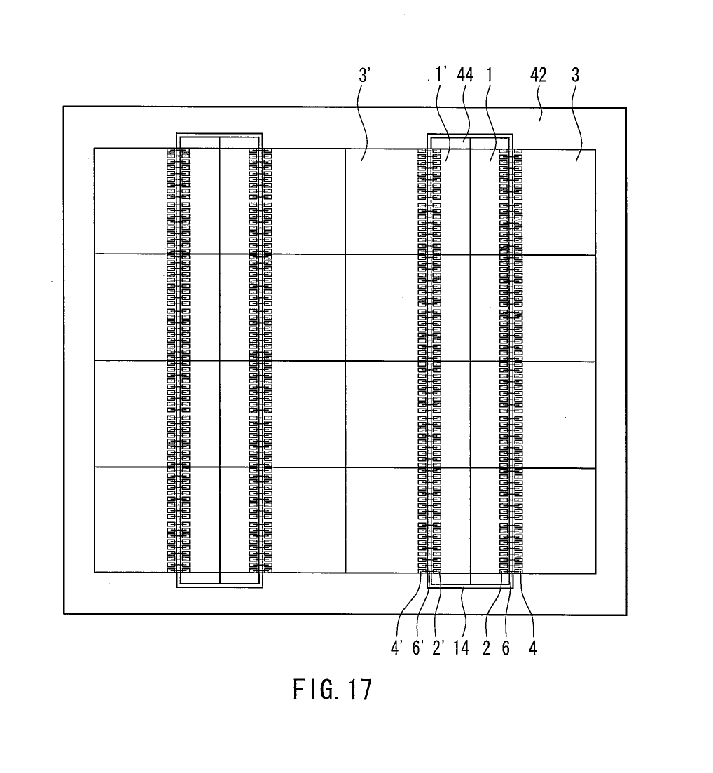

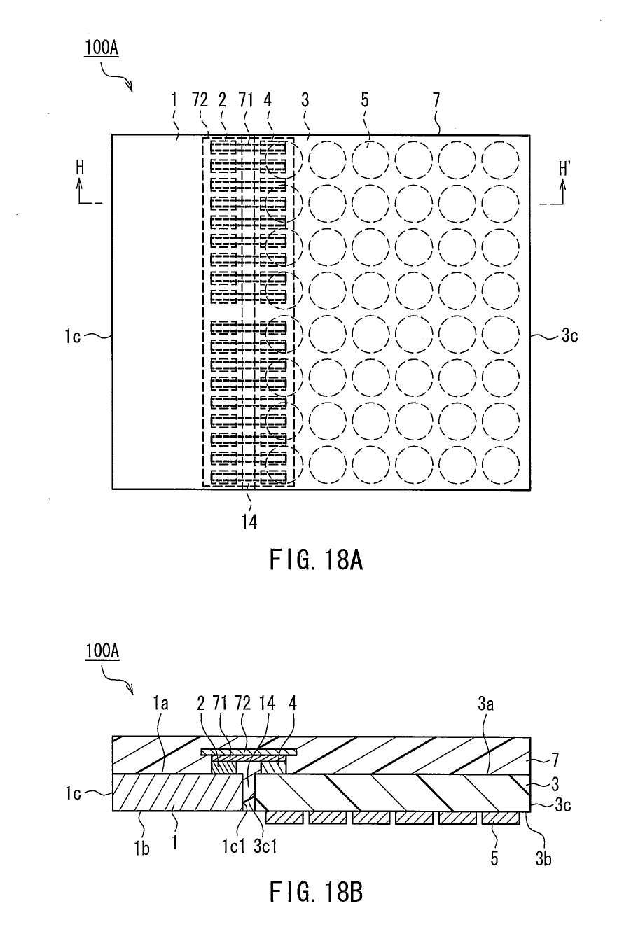

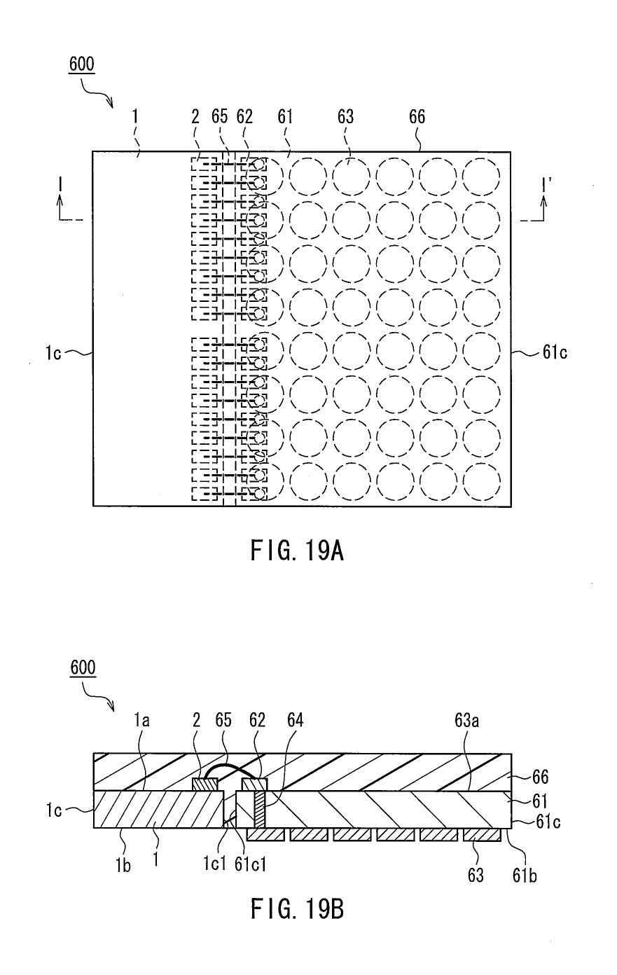

### BRIEF DESCRIPTION OF DRAWINGS

[FIG. 1] FIG. 1 is a diagram showing a configuration of a semiconductor device according to a first embodiment of the present invention. FIG. 1A is a plan view of the configuration. FIG. 1B is a cross-sectional view of the configuration.

[FIG. 2] FIG. 2 is a diagram showing a configuration of a semiconductor device according to a first example application of the first embodiment of the present invention. FIG. 2A is a plan view of the configuration. FIG. 2B is a cross-sectional view of the configuration.

[FIG. 3] FIG. 3 is a diagram showing a configuration of another form of the semiconductor device of the first example application of the first embodiment of the present invention.

[FIG. 4] FIG. 4 is a diagram showing a configuration of a semiconductor device according to a second example application of the first embodiment of the present invention. FIG. 4A is a plan view of the configuration. FIG. 4B is a cross-sectional view of the configuration.

[FIG. 5] FIG. 5 is a plan view of a semiconductor device according to the first embodiment of the present invention in which a semiconductor element and a circuit board both have a triangular plan-view shape.

[FIG. 6] FIG. 6 is a diagram showing a configuration of a semiconductor device according to a second embodiment of the present invention. FIG. 6A is a plan view of the configuration. FIG. 6B is a cross-sectional view of the configuration.

[FIG. 7] FIG. 7 is a diagram showing a configuration of a first semiconductor package according to a third embodiment of the present invention. FIG. 7A is a plan view of the configuration. FIG. 7B is a cross-sectional view of the configuration.

[FIG. 8] FIG. 8 is a cross-sectional view of a configuration of a second semiconductor package according to the third embodiment of the present invention.

[FIG. 9] FIG. 9 is a cross-sectional view of a configuration of a third semiconductor package according to the third embodiment of the present invention.

[FIG. 10] FIG. 10 is a cross-sectional view of a configuration of a fourth semiconductor package according to the third embodiment of the present invention.

[FIG. 11] FIG. 11 is a cross-sectional view of a configuration of a fifth semiconductor package according to the third embodiment of the present invention.

[FIG. 12] FIG. 12 is a cross-sectional view of a configuration of a sixth semiconductor package according to the third embodiment of the present invention.

[FIG. 13] FIG. 13 is a cross-sectional view of a configuration of a seventh semiconductor package according to the third embodiment of the present invention.

[FIG. 14] FIG. 14 is a cross-sectional view of a configuration of an eighth semiconductor package according to the third embodiment of the present invention. FIG. 14A is a plan view of the configuration. FIG. 14B is a cross-sectional view of the configuration.

[FIG. 15] FIG. 15 is a cross-sectional view of a configuration of a ninth semiconductor package according to the third embodiment of the present invention. FIG. 15A is a plan view of the configuration. FIG. 15B is a cross-sectional view of the configuration. [FIG. 16] FIG. 16 is a cross-sectional view of a configuration of a semiconductor device, showing manufacturing steps of a semiconductor device manufacturing method according to a fourth embodiment of the present invention.

[FIG. 17] FIG. 17 is a plan view of the configuration of the semiconductor device, showing a state after a connecting step in the semiconductor device manufacturing method of the fourth embodiment of the present invention.

[FIG. 18] FIG. 18 is a diagram showing a configuration of a semiconductor device according to an embodiment of the present invention which includes a connector that is different from a connection wire. FIG. 18A is a plan view of the configuration. FIG. 18B is a cross-sectional view of the configuration. [FIG. 19] FIG. 19 is a cross-sectional view of a configuration of an implementation of a semiconductor device according to another embodiment. FIG. 19A is a plan view of the configuration. FIG. 19B is a cross-sectional view of the configuration.

[FIG. 20] FIG. 20 is a diagram showing manufacturing steps of a conventional semiconductor device manufacturing method.

### DESCRIPTION OF THE INVENTION

In a semiconductor device of the present invention, a semiconductor element having a first main surface on which a connection electrode is formed, a second main surface opposite to the first main surface, and a plurality of side surfaces, and a circuit board having a first main surface on which an electrode pad is formed, a second main surface opposite to the first main surface, and a plurality of side surfaces, are arranged so that while the first main surfaces of the semiconductor element and the circuit board face in the same direction and the side surfaces of the semiconductor element and the circuit board face each other, the connection electrode and the electrode pad are connected together. The first main surfaces of the semiconductor element and the circuit board are covered with an encapsulation resin.

With this configuration, the surfaces other than the first main surface of the semiconductor element can be exposed, whereby the heat dissipation characteristics of the semiconductor element can be significantly improved. The connection electrode on the first main surface of the semiconductor element and the electrode pad on the first main surface of the circuit board can be provided in the vicinity of the side surfaces substantially facing each other, whereby the flexibility of design of a circuit pattern of the semiconductor element and an interconnect pattern of the circuit board can be improved, compared to when the semiconductor element is surrounded by electrode pads arranged on the circuit board. Moreover, the semiconductor element and the circuit board that do not have useless space can be obtained, whereby the size of the semiconductor device can be reduced. A plurality of semiconductor elements and circuit boards can be connected together simultaneously, whereby the productivity of the semiconductor device can be improved.

In the above configuration of the semiconductor device of the present invention, at least one of the side surfaces of the semiconductor element preferably is exposed without being covered with the encapsulation resin. With this configuration, the number of surfaces of the semiconductor element that are not covered with the encapsulation resin is increased, resulting in higher heat dissipation characteristics.

There may be a plurality of the circuit boards, and the plurality of circuit boards may substantially face two or more of the side surfaces of the semiconductor element. With this configuration, a semiconductor device in which an increasing number of terminals can be provided on the semiconductor element can be obtained easily.

There may be a plurality of the semiconductor elements, and the plurality of semiconductor elements may substantially face two or more of the side surfaces of the circuit board. With this configuration, a semiconductor device in which an increasing number of chips (semiconductor elements) can be provided can be easily obtained.

An integrated circuit may be formed on the second main surface of the semiconductor element and connected to the connection electrode formed on the first main surface of the semiconductor element by a connection interconnect penetrating through the semiconductor element. With this configuration, the heat dissipation of the semiconductor element can be performed more effectively.

In a semiconductor package of the present invention, any one of the above semiconductor devices of the present invention is mounted on an external circuit board, and the external electrode formed on the second main surface of the circuit board included in the semiconductor device is connected to a mounted electrode terminal formed on a mounting surface of the external circuit board on which the semiconductor device is mounted.

With this configuration, a semiconductor package that takes advantage of the features of the semiconductor device of the present invention can be obtained.

In the semiconductor package of the present invention, the semiconductor element included in the semiconductor device may protrude laterally from the external circuit board. With this configuration, the semiconductor element can be exposed without being covered by the external circuit board, whereby the heat dissipation characteristics can be improved.

At least one of the side surfaces and the second main surface of the semiconductor element included in the semiconductor device may contact heat dissipation portion. Thus, by making the heat dissipation portion directly contact with the semiconductor element, a semiconductor package in which the heat dissipation characteristics of the semiconductor element are improved significantly can be obtained.

A gap may be formed between the semiconductor element included in the semiconductor device and the external circuit board. With this configuration, a heat dissipation path can be ensured for the semiconductor element.

The gap between the semiconductor element and the external circuit board may be filled with an underfill. With this configuration, the heat dissipation capability of the semiconductor element can be ensured while sufficient connection characteristics between the circuit board and the external circuit board are maintained.

A semiconductor device manufacturing method of the present invention includes a placing step of placing, on a holding plate, a semiconductor element having a first main surface on which a connection electrode is formed, a second main surface opposite to the first main surface, and a plurality of side surfaces, and a circuit board having a first main surface on which an electrode pad is formed, a second main surface opposite to the first main surface, and a plurality of side surfaces, side by side with the first main surfaces of the semiconductor element and the circuit board facing in the same direction, a connecting step of connecting the connection electrode and the electrode pad together, an encapsulating step of covering the semiconductor element and the circuit board with an encapsulation resin, and a holding plate removing step of removing the holding plate.

With this configuration, it is possible easily to manufacture a semiconductor device in which the heat dissipation capability of a mounted semiconductor element can be improved, and the flexibility of circuit design of the semiconductor element and a circuit board and the productivity of the semiconductor element during a mounting step can be improved.

In the semiconductor device manufacturing method of the present invention, a plurality of the semiconductor elements continuously formed in a line may be mounted on the holding plate in the placing step, and the semiconductor element and the circuit board connected together may be singulated after the encapsulating step, and thereafter, the holding plate removing step may be performed. Alternatively, a plurality of the semiconductor elements continuously formed in a line may be mounted on the holding plate in the placing step, and the semiconductor element and the circuit board connected together may be singulated after the holding plate removing step.

With this configuration, a plurality of semiconductor elements can be mounted simultaneously on the holding plate, whereby the productivity of the semiconductor device can be improved significantly.

In the placing step, the semiconductor elements and the circuit boards may be arranged so that the semiconductor elements and the circuit boards in adjacent columns are symmetrical with respect to a point. With this configuration, semiconductor devices having the same configuration can be simultaneously can be manufactured with high efficiency.

A semiconductor device, semiconductor package, and semiconductor device manufacturing method according to the present invention will be described hereinafter by way of example with reference to the accompanying drawings.

### First Embodiment

Firstly, as a first embodiment of the present invention, a configuration of the semiconductor device of the present invention will be described.

FIG. 1 is a diagram showing a configuration of a semiconductor device 100 according to the first embodiment. FIG. 1A is a plan view of the configuration as viewed from above a first main surface of the semiconductor device 100. FIG. 1B is a cross-sectional view of the configuration taken along arrowed line A-A′ of FIG. 1A.

As shown in FIG. 1, the semiconductor device 100 of this embodiment includes: a semiconductor element 1 having a first main surface 1a on which connection electrodes 2 are formed, a second main surface 1b opposite to the first main surface 1a, and side surfaces 1c substantially perpendicular to the first main surface 1a and the second main surface 1b; and a circuit board 3 having a first main surface 3a on which electrode pads 4 are formed, a second main surface 3b opposite to the first main surface 3a, and side surfaces 3c substantially perpendicular to the first main surface 3a and the second main surface 3b. In the semiconductor device 100 of this embodiment of FIG. 1, the main surfaces (1a, 1b, 3a, and 3b) of the semiconductor element 1 and the circuit board 3 are in the shape of substantially a rectangle, and therefore, the semiconductor element 1 and the circuit board 3 each have four side surfaces 1c or 3c. However, as described below, the shapes of the main surfaces of the semiconductor element 1 and the circuit board 3 are not limited to those shown in FIG. 1, and may be other shapes, such as a triangular shape etc., and therefore, the number of the side surfaces 1c or 3c is not limited to four.

Although FIG. 1 shows an example in which the side surfaces 1c and 3c are substantially perpendicular to the first main surfaces 1a and 3a and the second main surfaces 1b and 3b, the angles between the side surfaces and the two main surfaces are not limited to this. Moreover, although FIG. 1 shows that the side surfaces (1c and 3c) of the semiconductor element 1 and the circuit board 3 are each perfectly flat, the side surfaces (1c and 3c) are not limited to flat surfaces. In the semiconductor element 1 and the circuit board 3, any surface that links the first main surface and the second main surface, such as a smooth curved surface or triangular surface having an outwardly convex or concave cross-section, etc., may be recognized as the side surface (1c, 3c).

The semiconductor element 1 and the circuit board 3 are arranged side by side so that the first main surface 1a of the semiconductor element 1 and the first main surface 3a of the circuit board 3 face in the same direction, i.e., upward in FIG. 1B, and one side surface 1c1 of the semiconductor element 1 and one side surface 3c1 of the circuit board 3 substantially face each other. Note that, as used herein, the term “a side surface of a semiconductor element and a side surface of a circuit board substantially face each other” means that at least a portion of the side surface of the semiconductor element and at least a portion of the side surface of the circuit board face each other, and is not limited only to the case where the two entire side surfaces completely face each other. As used herein, the concept that the side surfaces substantially face each other encompasses a state in which the side surfaces are displaced from each other along one of the main surface directions, but planes containing the side surfaces face each other.

As shown in FIG. 1A, the connection electrodes 2 formed on the first main surface 1a of the semiconductor element 1 are arranged in a line along a side formed by the side surface 1c1 facing the circuit board 3, i.e., along the right side in the figure. The electrode pads 4 formed on the first main surface 3a of the circuit board 3 are arranged along a side formed by the side surface 3c1 facing the semiconductor element 1, i.e., along the left side in the figure. In other words, the connection electrodes 2 and the electrode pads 4 are formed in portions of the first main surfaces 1a and 3a at which the distance between the semiconductor element 1 and the circuit board 3 is smallest. The connection electrodes 2 are connected to the respective corresponding electrode pads 4 by wire bonding using connection wires (connectors) 6 made of a metal.

An encapsulation resin 7 made of epoxy resin etc. is formed to cover the first main surface 1a of the semiconductor element 1, the first main surface 3a of the circuit board 3, and the connection wires 6 that provide electrical conduction between the connection electrodes 2 and the electrode pads 4. In the semiconductor device 100 of this embodiment, a gap 14 between the semiconductor element 1 and the circuit board 3 is also filled with the encapsulation resin 7, whereby the semiconductor element 1 and the circuit board 3 are integrally and firmly bonded together.

A plurality of external electrodes 5 corresponding to a circuit pattern (not shown) formed on the circuit board 3 are formed on the second main surface 3b of the circuit board 3. In the semiconductor device 100 of this embodiment, the external electrodes 5 are regularly arranged in rows and columns, i.e., in a matrix. This is merely illustrative. The arrangement of the external electrodes 5 is not limited.

As described above, in the semiconductor device 100 of this embodiment, the semiconductor element 1 and the circuit board 3 are arranged so that the first main surfaces 1a and 3a thereof face in the same direction, and one (1c1) of the side surfaces of the semiconductor element 1 and one (3c1) of the side surfaces of the circuit board 3 substantially face each other. In addition, the connection electrodes 2 and the electrode pads 4 provided in the proximity of the sides formed by the side surfaces 1a and 3c1 substantially facing each other, are connected together via the connection wires 6. Moreover, the first main surface 1a of the semiconductor element 1, the first main surface 3a of the circuit board 3, and the connection wires 6 are covered with the encapsulation resin 7. With this configuration, while the connection between the connection electrodes 2 and the electrode pads 4 is ensured and the semiconductor element 1 and the circuit board 3 are integrated together to form the semiconductor device 100, the side surfaces other than the side surface 1a facing the circuit board 3, and the second main surface 1b (bottom surface), of the semiconductor element 1 can be exposed. Therefore, the heat dissipation characteristics of the semiconductor element 1 can be improved.

Note that, in the semiconductor device 100 of this embodiment of FIG. 1, the gap 14 between the semiconductor element 1 and the circuit board 3 is also filled with the encapsulation resin 7. Alternatively, as long as the semiconductor element 1 and the circuit board 3 can be integrated together with sufficient strength, the present invention does not necessarily require that the gap 14 be filled with the encapsulation resin 7. If the gap 14 between the semiconductor element 1 and the circuit board 3 is not filled with an encapsulation resin, each of five surfaces (i.e., the second main surface 1b and the four side surfaces 1c) other than the first main surface 1a of the semiconductor element 1 is exposed without being covered with the encapsulation resin 7, resulting in the semiconductor device 100 in which the heat dissipation characteristics of the semiconductor element 1 are considerably high.

As shown in FIG. 1A, in the semiconductor device 100 of this embodiment, the semiconductor element 1 is provided at a side end portion of the entire semiconductor device 100 as viewed from above the first main surfaces 1a and 3a. Therefore, when a semiconductor package is formed in which the semiconductor device 100 is mounted on an external circuit board, heat dissipation means, such as a metal member, a heat sink fin or heat dissipation portion, etc., easily can contact with the second main surface 1b and the side surfaces 1c of the semiconductor element 1, compared to the case where the semiconductor element is surrounded by a circuit board or terminals as described in the Background Art section. Note that a specific example semiconductor package in which the semiconductor device of this embodiment is mounted on an external circuit board will be described below in a third embodiment.

In the semiconductor device 100 of this embodiment, the connection electrodes 2 of the semiconductor element 1 and the electrode pads 4 of the circuit board 3 are provided only in the vicinity of one side formed by the side surfaces 1c1 and 3c1 substantially facing each other of the main surfaces 1a and 3a. Therefore, compared to a conventional semiconductor device in which the connection electrodes 2 and the electrode pads 4 are arranged in substantially a rectangular ring, the arrangements of the circuit pattern of the semiconductor element 1 and the interconnect pattern of the circuit board 3 advantageously can be designed without constraints being imposed by the arrangements and positions of the connection electrodes 2 and the electrode pads 4, respectively.

Next, a first example application of the semiconductor device of the first embodiment of the present invention will be described with reference to FIG. 2.

FIG. 2 is a diagram showing a configuration of a semiconductor device 200 of the first example application of this embodiment.

FIG. 2A is a plan view of the configuration as viewed from above a first main surface of the semiconductor device 200. FIG. 2B is a cross-sectional view of the configuration taken along arrowed line B-B′ of FIG. 2A. Note that, in FIG. 2, the same components as those of the semiconductor device 100 of this embodiment of FIG. 1 are indicated by the same reference characters and will not be described in detail.

In the semiconductor device 200 of the first example application of this embodiment of FIG. 2, two semiconductor elements 1 and 8 are arranged substantially to face two side surfaces of a single circuit board 3. In other words, in the semiconductor device 100 of this embodiment of FIG. 1, a side surface 8c 1 of the second semiconductor element 8 faces a side surface 3c2 that is opposite to the side surface 3c1 that the semiconductor element 1 substantially faces, of the four side surfaces 3c of the circuit board 3. Therefore, on the first main surface 3a of the circuit board 3, electrode pads 4 are formed in the vicinity of a side formed by the side surface 3c1 adjacent to the first semiconductor element 1 while electrode pads 4 also are formed in a line in the vicinity of a side formed by the side surface 3c2, which is opposite to that side.

The circuit board 3 and the second semiconductor element 8 are connected together in a manner similar to that in which the circuit board 3 is connected to the semiconductor element 1. Specifically, the electrode pads 4 arranged in a line in the vicinity of the side formed by the side surface 3c2 of the circuit board 3, are connected to connection electrodes 9 that are formed on a first main surface 8a of the second semiconductor element 8 by connection wires 10. An encapsulation resin 7 is formed to cover the first main surface 3a of the circuit board 3, the first main surface 1a of the semiconductor element 1, the first main surface 8a of the second semiconductor element 8, and the connection wires 6 and 10.

Note that, as in the basic configuration of the semiconductor device 100 of FIG. 1, a plurality of external connection terminals 5 are arranged in a matrix on the second main surface 3b of the circuit board 3, and gaps 14 between the semiconductor elements 1 and 8 and the circuit board 3 are filled with the encapsulation resin 7.

Thus, in the semiconductor device of the first example application of this embodiment, two semiconductor elements are arranged substantially to face two side surfaces of a single circuit board. As a result, the heat dissipation characteristics of the semiconductor elements can be improved, and the flexibility of design of the arrangement of an interconnect pattern on the semiconductor element and the circuit board can be improved (advantages of the semiconductor device of the present invention), and in addition, the semiconductor device can have a more complicated processing function. Note that the two semiconductor elements 1 and 8 may, of course, have either the same or different functions.

In FIG. 2, the side surfaces 1a and 8c1 of the semiconductor elements 1 and 8 substantially face the side surfaces 3c1 and 3c2, respectively, that are located on opposite sides of the circuit board 3. Alternatively, the side surfaces of the circuit board 3 that the side surfaces of the semiconductor element substantially face are not limited to the opposite side surfaces of FIG. 2, and may be two adjacent side surfaces selected from the four side surfaces. A single circuit board and three or more semiconductor elements may be used and arranged so that side surfaces of the three or more semiconductor elements substantially face three or more side surfaces of the circuit board. Alternatively, side surfaces of a plurality of semiconductor elements may substantially face a single side surface of a circuit board.

FIG. 3 is a plan view showing another form of the semiconductor device of the first example application of the first embodiment of the present invention. FIG. 3 corresponds to FIG. 2A showing the first example application of the semiconductor device of the first embodiment of the present invention. Note that, in FIG. 3, the same components as those of the semiconductor device 200 of the first example application of this embodiment of FIG. 2 are indicated by the same reference characters and will not be described in detail.

In the semiconductor device 200A of FIG. 3 in another form of the first example application, four semiconductor elements 1, 8, 11, and 15 are arranged substantially to face four side surfaces of a single circuit board 3. Specifically, in the semiconductor device 200 of the first example application of this embodiment whose plan view is shown in FIG. 2A, the semiconductor elements 11 and 15 are arranged substantially to face the remaining side surfaces 3c3 and 3c4 of the circuit board 3.

Therefore, on the first main surface 3a of the circuit board 3, electrode pads 4 are provided in a line in the vicinity of a side formed by the side surface 3c1 adjacent to the first the semiconductor element 1, and electrode pads 4 also are provided in a line in the vicinity of a side formed by the opposite side surface 3c2, and in addition, electrode pad 4 are provided in a line in the vicinity of a side formed by the side surface 3c3 adjacent to the third semiconductor element 11, and electrode pad 4 are provided in a line in the vicinity of a side formed by the side surface 3c4 adjacent to the fourth semiconductor element 15.

The circuit board 3 is connected to the third semiconductor element 11 in a manner similar to that in which the circuit board 3 is connected to the semiconductor elements 1 and 8. Specifically, the electrode pads 4 provided in a line in the vicinity of the side formed by the side surface 3c3 of the circuit board 3 are connected to connection electrodes 12 formed on a first main surface 11a of the third semiconductor element 11 by connection wires 13. The electrode pads 4 provided in a line in the vicinity of the side formed by the side surface 3c4 of the circuit board 3 are connected to connection electrodes 16 formed on a first main surface 15a of the fourth semiconductor element 15 by connection wires 17. Moreover, an encapsulation resin 7 is formed to cover the first main surface 3a of the circuit board 3, the first main surface 1a of the semiconductor element 1, the first main surface 8a of the semiconductor element 8, the first main surface 11a of the semiconductor element 11, the first main surface 15a of the semiconductor element 15, and the connection wires 6, 10, 13, and 17.

Note that, as in the configuration of the semiconductor device 200 of the first example application of FIG. 2A, a plurality of external connection terminals 5 are arranged in a matrix on the second main surface 3b of the circuit board 3, and gaps 14 between the semiconductor elements 1, 8, 11, and 15 and the circuit board 3 are filled with the encapsulation resin 7.

Next, a second example application of the semiconductor device of the first embodiment of the present invention will be described with reference to FIG. 4.

FIG. 4 is a diagram showing a configuration of a semiconductor device 300 of the second example application of this embodiment. FIG. 4A is a plan view of the configuration as viewed from above a first main surface of the semiconductor device 300. FIG. 4B is a cross-sectional view of the configuration taken along arrowed line C-C′ of FIG. 4A. Note that, also in FIG. 4, similar to FIG. 2, the same components as those of the semiconductor device 100 of this embodiment whose basic configuration is shown in FIG. 1 and will not be described in detail.

In the semiconductor device 300 of the second example application of this embodiment of FIG. 4, two circuit boards 3 and 18 are arranged to substantially face two side surfaces of a single semiconductor element 1. Specifically, in the semiconductor device 100 of this embodiment of FIG. 1, a side surface 18c1 of the second circuit board 18 substantially faces one (1c2) of the four side surfaces 1c of the semiconductor element 1 that is opposite to the side surface 1c1 that the circuit board 3 substantially faces. Therefore, on the first main surface 1a of the semiconductor element 1, connection electrodes 2 are formed in the vicinity of a side formed by the side surface 1a adjacent to the first the circuit board 3, and connection electrodes 2 are also formed in a line in the vicinity of a side formed by the side surface 1c2, which is opposite to that side.

The semiconductor element 1 is connected to the second circuit board 18 in a manner similar to that in which the semiconductor element 1 is connected to the circuit board 3. Specifically, the connection electrodes 2 arranged in a line in the vicinity of the side formed by the side surface 1c2 of the semiconductor element 1 are connected to electrode pads 19 formed on a first main surface 18a of the second circuit board 18 by connection wires 20. Moreover, an encapsulation resin 7 is formed to cover the first main surface 1a of the semiconductor element 1, the first main surface 3a of the circuit board 3, the first main surface 18a of the second circuit board 18, and the connection wires 6 and 20.

Note that, similar to the second main surface 3a of the circuit board 3, a plurality of external connection terminals 5 are arranged in a matrix on a second main surface 18b of the second circuit board 11. As in the basic configuration of the semiconductor device 100 of FIG. 1, gaps 14 between the semiconductor element 1 and the circuit boards 3 and 18 are filled with the encapsulation resin 7.

Thus, in the semiconductor device of the second example application of this embodiment, two circuit boards are arranged substantially to face two side surfaces of a single semiconductor element. As a result, the heat dissipation characteristics of the semiconductor element can be improved, and the flexibility of design of the arrangement of an interconnect pattern on the semiconductor element and the circuit boards can be improved (advantages of the semiconductor device of the present invention), and in addition, the semiconductor device can include a semiconductor element having a larger number of terminals. Note that the two circuit boards 3 and 18 may, of course, have either the same or different interconnect patterns.

As in the first example application of this embodiment described above with reference to FIG. 2, FIG. 4 does not impose a constraint on the position relationship between a semiconductor element and two circuit boards (as to which of the side surfaces of the semiconductor element a side surface of each circuit board substantially faces), the number of circuit boards connected to a single semiconductor element, and the number of circuit boards substantially facing one side surface of a semiconductor element.

As the first embodiment of the present invention, the semiconductor device of the present invention and the semiconductor package including the semiconductor device have been described specifically. The above description is merely illustrative, and the semiconductor device of the present invention is not limited to those described above.

For example, the semiconductor devices of the present invention shown as the first embodiment in FIGS. 1, 2, 3, and 4, the first main surfaces of the semiconductor element(s) and the circuit board(s) all have the same height, but may not necessarily have the same height. In particular, when the semiconductor element and the circuit board have different thicknesses, then if the second main surfaces of the semiconductor element and the circuit board are on the same plane, the first main surfaces of the semiconductor element and the circuit board may have different heights. Even in this case, if the connection electrodes of the semiconductor element and the electrode pads of the circuit board can be connected together by connection wires, and the top surfaces of these components can be integrally encapsulated using an encapsulation resin, the present invention is applicable without any particular problem. As described above, the side surface of the semiconductor element and the side surface of the circuit board are not necessarily positioned at the same height so that the side surfaces directly face each other.

Note that, in an actual semiconductor device, the top surface of the connection electrodes of the semiconductor element and the top surface of the electrode pads of the circuit board are preferably positioned at the same height in order to connect the connection electrodes and the electrode pads together by connection wires. However, in some cases, the connection electrode and the electrode pad have different thicknesses. Alternatively, in some cases, the number of connection electrodes or electrode pads provided in a line in the vicinity of a side is limited and therefore connection electrodes or electrode pads need to be arranged in a plurality of lines. In these cases, different heights may be deliberately imparted to the semiconductor element and the circuit board in order to prevent connection wires from contacting each other. Thus, the first main surface of the semiconductor element and the first main surface of the circuit board may be deliberately positioned at different heights.

In the semiconductor devices of the present invention of FIGS. 1, 2, 3, and 4, the gap(s) between the semiconductor element(s) and the circuit board(s) is also filled with an encapsulation resin. However, this feature is not necessarily required by the semiconductor device of the present invention. If the gap between the semiconductor element and the circuit board is not filled with an encapsulation resin, only the first main surface of the six surfaces of the semiconductor element is covered with an encapsulation resin, and therefore, the heat dissipation characteristics of the semiconductor element can be improved further.

On the other hand, in the semiconductor device, if the integration of the semiconductor element and the circuit board is more desirable than an improvement in the heat dissipation characteristics of the semiconductor element, the encapsulation resin may be extended to side surfaces of the semiconductor element other than one that faces the circuit board. With this configuration, the semiconductor element and the circuit board can be firmly bonded together in the semiconductor device. In this case, the encapsulation resin may be extended to any of the three remaining side surfaces of the semiconductor element, and of course, a plurality of side surfaces may be covered with the encapsulation resin. If all side surfaces are covered with the encapsulation resin, only the second main surface of the semiconductor element is exposed. Note that if at least one side surface of the semiconductor element is exposed without being covered with the encapsulation resin, the heat dissipation characteristics are higher than when only the second main surface of the semiconductor element is exposed. Moreover, if the exposed side surface is in contact with a heat dissipator, such as a heat sink fin etc., heat of the semiconductor element can be dissipated more efficiently.

The gap between the semiconductor element and the circuit board may be filled with a filler made of another resin material etc. instead of the encapsulation resin.

In the semiconductor devices of the present invention of FIGS. 1, 2, 3, and 4, the main surfaces of the semiconductor element and the circuit board all have a rectangular shape by way of example. The semiconductor device of the present invention is not limited to this. The semiconductor element and the circuit board may have various other shapes, such as a square, a trapezoid, a rhombus, a triangle, a polygon (five or more sided polygons), etc. The semiconductor element and the circuit board do not necessarily have the same shape, and may have shapes that are both rectangular but have different lengths. Alternatively, for example, the circuit board may have substantially an L- or U-shape, and the semiconductor element may be fitted in the hollowed portion of the L- or U-shape of the circuit board, whereby the entire semiconductor device may have a rectangular or square plan-view shape.

As a specific example in which the semiconductor element and the circuit board have shapes other than a quadrangular shape, a case where the semiconductor element and the circuit board both have a triangular shape is shown in FIG. 5.

In a semiconductor device 400 shown in FIG. 5, a semiconductor element 21 and a circuit board 23 both having a triangular plan-view shape are arranged side by side so that a side surface 21c1 (corresponding to the hypotenuse of the triangle) of the semiconductor element 21 faces a side surface 23c1 (corresponding to the hypotenuse of the triangle) of the circuit board 23, and a first main surface 21a of the semiconductor element 21 and a first main surface 23a of the circuit board 23 face in the same direction, i.e., toward the viewer of FIG. 5.

As shown in FIG. 5, a plurality of connection electrodes 22 provided in the vicinity of the side surface 21c1 (corresponding to the hypotenuse of the first main surface 21a) of the semiconductor element 21, are connected to a plurality of electrode pads 24 provided in the vicinity of the side surface 23c1 (corresponding to the hypotenuse of the first main surface 23a) of the circuit board 23 by connection wires 26. An encapsulation resin 27 is formed to cover the first main surface 21a of the semiconductor element 21, the first main surface 23a of the circuit board 23, and the connection wires 26.

Thus, by using the semiconductor element 21 having a triangular plan-view shape and the circuit board 23 having a triangular plan-view shape, side surfaces and the second main surface (bottom surface) of the semiconductor element 21 can be exposed. As a result, the semiconductor device can have a high heat dissipation effect (advantage of the present invention), and in addition, the connection electrodes 22 and the electrode pads 24 can be provided along the hypotenuses (long sides) of the semiconductor element 21 and the circuit board 23, and therefore, the entire semiconductor device 400 can have a compact plan-view shape while accommodating an increasing number of pins on the semiconductor element.

### Second Embodiment

Next, as a second embodiment of the present invention, another example configuration of the semiconductor device of the present invention will be described.

FIG. 6 is a diagram showing a configuration of a semiconductor device 500 according to the second embodiment of the present invention. FIG. 6A is a plan view of the configuration as viewed from above a first main surface of the semiconductor device 500. FIG. 6B is a cross-sectional view of the configuration taken along arrowed line D-D′ of FIG. 6A.

The semiconductor device 500 of this embodiment of FIG. 6 includes a circuit board 3 having the same configuration as that of the circuit board 3 in the semiconductor device 100 of the first embodiment of the present invention described with reference to FIG. 1. The semiconductor device 500 also includes a semiconductor element 31 that includes connection electrodes 2 on a first main surface 31a and a semiconductor integrated circuit 32 on a second main surface 31b (bottom surface). Connection interconnects 33 connecting the connection electrodes 2 and the integrated circuit 32 together are formed to penetrate through the board of the semiconductor element 31. Thus, the semiconductor element 31 is different from the semiconductor element 1 of the semiconductor device 100 of the first embodiment.

Specifically, the semiconductor device 500 of this embodiment includes: the semiconductor element 31 having the first main surface 31a on which the connection electrodes 2 are formed, the second main surface 31b that is opposite to the first main surface 31a and on which the integrated circuit 32 is formed, and side surfaces 31c substantially perpendicular to the first main surface 31a and the second main surface 31b; and the circuit board 3 having a first main surface 3a on which electrode pads 4 are formed, a second main surface 3b that is opposite to the first main surface 3a and on which external electrodes 5 are formed, and side surfaces 3c substantially perpendicular to the first main surface 3a and the second main surface 3b. Note that, also in this embodiment, the shapes of the main surfaces of the semiconductor element 31 and the circuit board 3 are not limited, and the angles between the side surface and the two main surfaces are not limited, and there is no constraint that the side surface is flat, as in the semiconductor device 100 of the first embodiment.

Also in the semiconductor device 500 of this embodiment, the semiconductor element 31 and the circuit board 3 are arranged side by side so that the first main surface 31a of the semiconductor element 31 and the first main surface 3a of the circuit board 3 face in the same direction, i.e., upward in FIG. 6B, one (31c1) of the side surfaces of the semiconductor element 31 and one (3c1 ) of the side surfaces of the circuit board 3 substantially face each other. The connection electrodes 2 are arranged on the first main surface 31a of the semiconductor element 31 in a manner similar to that of the semiconductor device 100 of the first embodiment. Moreover, an encapsulation resin 7 made of epoxy resin etc. is formed to cover the first main surface 31a of the semiconductor element 31, the first main surface 3a of the circuit board 3, and connection wires 6 that provide electrical conduction between the connection electrodes 2 and the electrode pads 4, as in the semiconductor device 100 of the first embodiment. Also in the semiconductor device 500 of this embodiment, a gap 14 between the semiconductor element 31 and the circuit board 3 is also filled with the encapsulation resin 7, whereby the semiconductor element 31 and the circuit board 3 are integrally and firmly bonded together.

Thus, the integrated circuit 32, which is a heat source of the semiconductor element 31, can be exposed without being covered with the encapsulation resin 7. Therefore, the semiconductor device 500 can have higher heat dissipation characteristics than those described in the first embodiment.

Note that, although not shown, also in this embodiment, as in the first example application described above in the first embodiment with reference to FIG. 2, a plurality of semiconductor elements may be connected to a single circuit board, or as in the second example application described with reference to FIG. 4, a single semiconductor element may be connected to a plurality of circuit boards. In all of the example applications, the integrated circuit, which is a heat source of the semiconductor element, can be exposed without being covered by the encapsulation resin, whereby the semiconductor device can have high heat dissipation characteristics.

Also, in the semiconductor device 500 of this embodiment of FIG. 6, the encapsulation resin 7 is formed on the first main surface 31a of the semiconductor element 31 and the first main surface 3a of the circuit board 3, and all the side surfaces other than the side surfaces 31c1 and 3c1 substantially facing each other at a portion corresponding to the gap 14 between the semiconductor element 31 and the circuit board 3, are exposed without being covered with the encapsulation resin 7. Alternatively, the side surfaces of the semiconductor element 31 may be covered with the encapsulation resin 7. If at least one of the side surfaces 31c of the semiconductor element 31 is exposed without being covered with the encapsulation resin 7, the heat dissipation characteristics are higher than when only the second main surface 31b of the semiconductor element 31 is exposed. Moreover, if a heat dissipator, such as a heat sink fm etc., is made contact with the exposed side surface 31c, heat of the semiconductor element can be more efficiently dissipated.

### Third Embodiment

Next, as a third embodiment of the present invention, a semiconductor package in which the semiconductor device of the present invention of the first or second embodiment is mounted will be specifically described with reference to the drawings.

FIG. 7 is a diagram showing a configuration of a first semiconductor package 1000 according to the third embodiment of the present invention. FIG. 7A is a plan view of the configuration as viewed from above the first main surface of the semiconductor element 1. FIG. 7B is a cross-sectional view of the configuration taken along arrowed line E-E′ of FIG. 7A.

As shown in FIG. 7, in the first semiconductor package 1000 of this embodiment, the semiconductor device 100 of the first embodiment of the present invention is mounted on an external circuit board 110, such as a motherboard etc. Specifically, mounted electrode terminals 120 formed on a mounting surface 110a of the external circuit board 110 on which the semiconductor device 100 is mounted (i.e., the mounting surface 110a facing the second main surface 3b of the circuit board 3), and the external electrodes 5 formed on the second main surface 3b of the circuit board 3, are bonded together by an electrode bonding material 130, such as solder, electrically conductive paste, etc. On the external circuit board 110, a drive power supply for driving the semiconductor device 100, various control elements, and a signal control circuit for controlling input and output signals of the semiconductor device 100, etc. are mounted.

As shown in FIGS. 7A and 7B, in the first semiconductor package 1000 of this embodiment, the semiconductor element 1 can be provided at a side end portion of the entire semiconductor device 100 (a left side in FIG. 7), and therefore, can protrude laterally from the external circuit board 110. In other words, while the circuit board 3 of the semiconductor device 100 is provided on the external circuit board 110, the semiconductor element 1 integrated with the circuit board 3 by the encapsulation resin 7 is provided at a position that is not on the external circuit board 110, i.e., to the left of the external circuit board 110 in FIG. 7. With this configuration, the semiconductor element 1 more easily can be exposed to ambient atmosphere.

Although, in FIG. 7, the entire semiconductor element 1 protrudes laterally from the external circuit board 110, the semiconductor package of the present invention is not limited to this. Alternatively, if a portion of the semiconductor element 1 protrudes from the external circuit board 110, the semiconductor element 1 can have high heat dissipation characteristics.

FIG. 8 is a cross-sectional view of a configuration of a second semiconductor package 1100 according to the third embodiment of the present invention.

In the second semiconductor package 1100 of this embodiment of FIG. 8, as in the first semiconductor package 1000 of FIG. 7, the semiconductor device 100 of the first embodiment of the present invention is mounted on an external circuit board 110. In the second semiconductor package 1100, a heat sink plate 140 for heat dissipation of the semiconductor element 1 is attached by an adhesive 150 to the bottom surface (i.e., the second main surface 1b) of the semiconductor element 1 protruding laterally from the external circuit board 110.

Here, the heat sink plate 140 may be made of a metal, such as Al, Cu, etc. The adhesive 150 preferably has both adhesion properties and heat conductivity. Examples of the adhesive 150 include inorganic compounds (alumina, silica, silicon nitride, etc.), and epoxy resin, acrylic resin, and silicone resin, etc. in which a metal filler (Al, Cu, silver, etc.) is dispersed.

Note that when the heat sink plate 140 is used to increase the heat dissipation effect, the heat sink plate 140 may be attached to the second main surface (bottom surface) 1b of the semiconductor element 1 by a metal material, such as solder etc. In this case, it is preferable that a metal film made of Ni, Cu, Ni/Au, Pd, Ag, or the like be previously formed on the semiconductor element 1 or the heat sink plate 140 in order to bond the semiconductor element 1 and the heat sink plate 140 together.

Thus, in the second semiconductor package 1100 of this embodiment, the heat sink plate 140 can be made direct contact with the exposed second main surface 1b of the semiconductor element 1 of the semiconductor device 100 mounted on the external circuit board 110. Also, the size and shape of the heat sink plate 140 can be adapted to be less interfered with by the external circuit board 110 on which the semiconductor device 100 is mounted. Therefore, the semiconductor package 1100 can include the semiconductor element 1 having high heat dissipation characteristics.

Next, FIG. 9 is a cross-sectional view of a configuration of a third semiconductor package 1200 according to a third embodiment of the present invention.

In the third semiconductor package 1200 of this embodiment of FIG. 9, as in the second semiconductor package 1100 of FIG. 8, a heat sink plate is attached by an adhesive to a semiconductor element 1 protruding from an external circuit board 110. In the third semiconductor package 1200 of this embodiment, as shown in FIG. 9, an outer shape of a heat sink plate 145 is cut to fit a shape of the semiconductor element 1. As a result, the heat sink plate 145 can be attached by an adhesive 155 not only to a second main surface 1b of the semiconductor element 1 but also to a side surface 1c3 that is opposite to a circuit board 3, whereby the heat dissipation characteristics of the semiconductor element 1 can be improved further.

Although, also in FIGS. 8 and 9, the entire semiconductor element 1 protrudes laterally from the external circuit board 110, the semiconductor package of the present invention is not limited to this. Alternatively, a portion of the semiconductor element 1 may protrude from the external circuit board 110. In this case, the heat sink plate 140 or 145 easily can be attached to the semiconductor element 1, and the attachment of the heat sink plate 140 or 145 is advantageously not interfered with by the external circuit board 110.

Next, as a specific example of the semiconductor package of the third embodiment of the present invention, a case where the mounted semiconductor device does not protrude laterally from the external circuit board, will be described.

FIG. 10 is a cross-sectional view showing a configuration of a fourth semiconductor package 1300 of this embodiment.

As shown in FIG. 10, in the fourth semiconductor package 1300 of this embodiment, as in the first semiconductor package 1000 of FIG. 7, the external electrodes 5 provided on the second main surface 3b of the circuit board 3 in the semiconductor device 100 of the first embodiment of the present invention are bonded by an electrode bonding material 130 to mounted electrode terminals 120 formed on a semiconductor device mounting surface 110a of an external circuit board 110.

The semiconductor element 1 of the semiconductor device 100 is bonded by an adhesive 170 to a metal portion 160 formed on the mounting surface 110a of the external circuit board 110.

The metal portion 160 of the external circuit board 110 may be a metal film made of gold, aluminum, or solder, etc. that is formed by deposition etc. on the mounting surface 110a of the external circuit board 110 for the purpose of heat dissipation of the semiconductor element 1. The metal portion 160 is not limited to a member that is formed for heat dissipation of the semiconductor element 1. The metal portion 160 may be a metal portion of a circuit part mounted on the external circuit board 110, such as a semiconductor element having another integrated circuit, a peripheral part (an IC, a capacitor, a resistor, etc.), etc. Examples of the adhesive 170 include adhesives having high heat conductivity, such as inorganic compounds (alumina, silica, silicon nitride, etc.), and epoxy resin, acrylic resin, and silicone resin, etc. in which a metal filler (Al, Cu, silver, etc.) is dispersed, which are used to attach the heat sink plates 140 and 145 in the second semiconductor package 1100 and the third semiconductor package 1200 of this embodiment.

FIG. 11 is a cross-sectional view showing a configuration of a fifth semiconductor package 1400 of this embodiment.

In the fifth semiconductor package 1400 of this embodiment of FIG. 11, as in the fourth semiconductor package 1300 of FIG. 10, a semiconductor element 1 of a semiconductor device 100 mounted on an external circuit board 110 is bonded to the external circuit board 110. Unlike the fourth semiconductor package 1300 of FIG. 10, the semiconductor element 1 and the external circuit board 110 are bonded together with an electrode 180 formed on a second main surface 1b of the semiconductor element 1 being connected to a metal portion 165 formed on a mounting surface 110a of the external circuit board 110 by an electrode bonding material 175.

In the fifth semiconductor package 1400, the electrode 180 formed on the second main surface 1b of the semiconductor element 1 and external electrodes 5 formed on a second main surface 3b of a circuit board 3 have the same specifications, and a top layer of a metal portion 165 formed on the semiconductor device mounting surface 110a of the external circuit board 110 and mounted electrode terminals 120 on the external circuit board 110 have the same specifications. In this case, when the external electrodes 5 of the semiconductor device 100 and the mounted electrode terminals 120 mounted on the external circuit board 110 are connected together by an electrode bonding material 130, such as solder etc., the electrodes 180 of the semiconductor element 1 and the metal portion 165 formed on the semiconductor device mounting surface 110a of the external circuit board 110 simultaneously can be bonded together.

Note that, as a specific example of their specifications, the metal portion 165 formed on the semiconductor device mounting surface 110a of the external circuit board 110 and the top layer of the electrode terminals 120 mounted on the external circuit board 110 may be formed of Au/Ni and bonded by solder.

FIG. 12 is a cross-sectional view showing a configuration of a sixth semiconductor package 1500 of this embodiment.

The sixth semiconductor package 1500 of this embodiment of FIG. 12 is different from the fifth semiconductor package 1400 of FIG. 11 in that a pattern of electrodes 185 formed on a second main surface 1b of a semiconductor element 1 are connected to a patterned metal portion 167 formed on a semiconductor device mounting surface 110a of an external circuit board 110 and corresponding to that pattern, by an electrode bonding material 177.

In this case, in the second main surface 1b of the semiconductor element 1, the electrodes 185 of the semiconductor element 1 and external electrodes 5 of a semiconductor device 100 have the same bonding configuration, resulting in a uniform stress distribution, whereby the bonding reliability of the semiconductor package 1500 can be improved.

Note that the present invention does not necessarily require that the electrodes 180 formed on the second main surface 1b of the semiconductor element 1 and the external electrodes 5 formed on the second main surface 3b of the circuit board 3, in the semiconductor package 1400, have the same specifications as described above. The top layer of the electrode 180 formed on the second main surface 1b of the semiconductor element 1 may have any specifications that allow the electrode 180 of the semiconductor element 1 to bond to the metal portion 167 formed on the semiconductor device mounting surface 110a of the external circuit board 110. The top layer of the electrode 180 on the second main surface 1b of the semiconductor element 1 may have various specifications as long as this purpose is achieved.

FIG. 13 is a cross-sectional view showing a configuration of a seventh semiconductor package 1600 of this embodiment.

In the seventh semiconductor package 1600 of this embodiment of FIG. 13, a gap between a semiconductor element 1 of a semiconductor device 100 mounted on an external circuit board 110 and a mounting surface 110a of an external circuit board 110 is filled with an underfill 190.

FIG. 14 is a diagram showing a configuration of an eighth semiconductor package 2000 of this embodiment. FIG. 14A is a plan view of the configuration as viewed from above a first main surface 1a of a semiconductor element 1. FIG. 14B is a cross-sectional view of the configuration taken along arrowed line F-F′ of FIG. 14A.

In the eighth semiconductor package 2000 of this embodiment of FIGS. 14A and 14B, the semiconductor device 200 of the first example application of the first embodiment of the present invention is mounted on an external circuit board 210.

In the semiconductor device 200, the two semiconductor elements 1 and 8 are connected to both the left and right sides of the circuit board 3 provided at the middle as shown in FIG. 14. In the eighth semiconductor package 2000 of this embodiment, the external electrodes 5 formed on the second main surface 3b of the circuit board 3 provided at the middle and mounted electrode terminals 220 formed on the external circuit board 210 are bonded together by an electrode bonding material 230, and the surrounding thereof is filled with an underfill 240.

The underfill inherently has a function of improving the bonding reliability of the semiconductor package and a function of protecting the semiconductor element. Moreover, in the configuration of the seventh semiconductor package 1600 of this embodiment in which at least a portion of the semiconductor element is exposed outside an electrically bonding portion of the semiconductor device and the external circuit board, if a gap between the semiconductor element 1 and the external circuit board 110 is filled with an underfill made of an inorganic compound (alumina, silica, silicon nitride, etc.), or epoxy resin, acrylic resin, or silicone resin, etc. in which a metal filler (Al, Cu, silver, etc.) is dispersed, the heat dissipation capability of the semiconductor element 1 can be improved while the inherent functions of the underfill are provided.

Also, in the semiconductor device 200 of this embodiment, the semiconductor element 1 can be provided at a side end portion of the entire semiconductor device 200, and therefore, when the semiconductor package 2000 is formed, a space between the semiconductor element 1 and the external circuit board 210 can be broadened. Specifically, while the external electrodes 5 formed on the second main surface 3b of the circuit board 3 of the semiconductor device 200 and the mounted electrode terminals 220 formed on a semiconductor device 200 mounting surface 210a of the external circuit board 210 are connected together, a space having a predetermined size can be formed between the second main surface 1b of the semiconductor element 1 and the mounting surface 210a of the external circuit board 210. Therefore, even when an underfill 240 is provided to ensure satisfactory connection between the external electrodes 5 on the circuit board 3 of the semiconductor device 200 and the mounted electrode terminals 220 on the external circuit board 210, the semiconductor element 1 can be provided at a distance from the underfill 240. As a result, the semiconductor element 1 is not covered with the underfill 240, and for example, even when the underfill 240 has poor heat dissipation capability, high heat dissipation capability can be ensured for the semiconductor element 1.

Note that, in the semiconductor package of this embodiment, there is a space between the semiconductor element and the external circuit board, whereby the heat dissipation characteristics of the semiconductor element can be improved. Therefore, the semiconductor package of the present invention does not necessarily require that the space portion between the semiconductor element 1 and the external circuit board 210 is filled with an underfill or a resin material having high heat conductivity, etc.

FIG. 15 is a diagram showing a configuration of a ninth semiconductor package 3000 of this embodiment. FIG. 15A is a plan view of the configuration as viewed from a first main surface of a semiconductor element 1. FIG. 15B is a cross-sectional view of the configuration taken along arrowed line G-G′ of FIG. 15A.

In the ninth semiconductor package 3000 of this embodiment of FIGS. 15A and 15B, the semiconductor device 300 of the second example application of the first embodiment of the present invention is mounted on an external circuit board 310 and an external circuit board 320.

In the semiconductor device 300, two circuit boards 3 and 18 are connected to both left and right sides of the semiconductor element 1 provided at a middle as shown in FIG. 15. In the ninth semiconductor package 3000 of this embodiment, the external electrodes 5 formed on the second main surface 3b of the first circuit board 3 provided on the right side of the figure, and mounted electrode terminals 330 formed on the first external circuit board 310, are bonded together by an electrode bonding material 340. In addition, the external electrodes 5 formed on the second main surface 18b of the second circuit board 18 provided on the left side of the figure, and mounted electrode terminals 330 formed on the second external circuit board 320, are bonded together by the electrode bonding material 340.

Thus, in the ninth semiconductor package 3000 of this embodiment, the semiconductor device 300 is mounted on the two external circuit boards 310 and 320, straddling a space therebetween, and therefore, the second main surface 1b of the semiconductor element 1 can be exposed. Therefore, the semiconductor package 3000 can include the semiconductor element 1 having high heat dissipation characteristics.

As the third embodiment of the present invention, the example configurations of the first through ninth semiconductor packages have been specifically described with reference to the drawings. In the above description of this embodiment, for the sake of convenience, the semiconductor device 100 of the first embodiment (in the first through seventh semiconductor packages 1000-1700), the semiconductor device 200 of the first example application of the first embodiment (in the eighth semiconductor package 2000), and the semiconductor device 300 of the second example application of the first embodiment (in the ninth semiconductor package 3000), are mounted on the external circuit boards 110, 210, and 310 and 320, respectively. The semiconductor package of the present invention is not limited these examples. The features of each configuration are applicable to any of the semiconductor devices.

For example, in the second semiconductor package 1100 of this embodiment of FIG. 8 or the third semiconductor package 1200 of FIG. 9 in which a heat dissipation material is attached to the second main surface 1b of the semiconductor element 1, the semiconductor device 200 in which the two semiconductor elements 1 and 8 are connected to the single circuit board 3 may be used, or alternatively, the semiconductor device 300 in which the two circuit boards 3 and 18 are connected to the single semiconductor element 1 may be used.

Also, in the eighth semiconductor package 2000 of this embodiment of FIG. 14, the semiconductor device 100 or the semiconductor device 300 may be used, and the underfill 240 may be similarly applied to a bonding portion of the circuit board 3 or 18 and the external circuit board 110 or 310 and 320. Moreover, in the ninth the semiconductor device 3000 of FIG. 15 in which two external circuit boards are bonded to the semiconductor device 100 or the semiconductor device 200, the second main surface 1b of the semiconductor element 1 may be provided in an open space between the external circuit boards. In any of these cases, a semiconductor package in which high heat dissipation characteristics are obtained for a semiconductor element mounted therein can be provided.

### Fourth Embodiment

Next, as a fourth embodiment of the present invention, a method for manufacturing the semiconductor device of the present invention will be described with reference to the drawings.

FIG. 16 is a cross-sectional view of the configuration of the semiconductor device 100 of the first embodiment, showing steps of manufacturing the semiconductor device 100 shown in FIG. 1, according to the fourth embodiment of the present invention.

Note that, in FIG. 16, four semiconductor elements and four circuit boards are arranged in a horizontal direction of the figure, and moreover, as described below with reference to FIG. 17, four semiconductor elements and four circuit boards are arranged in respective columns, and the semiconductor elements and the circuit boards thus arranged in a matrix are connected together to form a total of 16 semiconductor devices, and thereafter, the semiconductor devices are separated from each other into individual ones (i.e., singulated). However, the number of semiconductor elements or circuit boards arranged in the length (column) or width (row) direction is, of course, not limited to four. If a single semiconductor device includes different numbers of semiconductor elements and circuit boards as in the example applications of the first embodiment described above with reference to FIGS. 2 and 4, then when the semiconductor device is manufactured by using the semiconductor device manufacturing method of this embodiment, the number of semiconductor elements arranged may, of course, be different from the number of circuit boards arranged.

Note that, in FIG. 16, the semiconductor element and the circuit board have the same configuration as that of the first embodiment described with reference to FIG. 1, and therefore, the same components as those described in the first embodiment are indicated by the same reference characters and will not be described in detail.

As shown in FIG. 16, in the semiconductor device manufacturing method of this embodiment, in the first sub-step of a placing step, initially, as shown in FIG. 16A, circuit boards 3 and 3′ in which electrode pads 4 and 4′ are formed on first main surfaces 3a and 3a′ and external electrodes 5 and 5′ are formed on second main surfaces 3b and 3b′, are provided on a holding plate 41 made of glass epoxy, plastic film, or metal plate, etc. with the first main surfaces 3a and 3a′ facing upward. Here, in the example of FIG. 16, in order to take advantage of a feature of the configuration of the semiconductor device of the present invention that the semiconductor element 1 and the circuit board 3 are arranged side by side so that side surfaces thereof face each other while main surfaces thereof face in the same direction, the orientations of the circuit board 3 and the semiconductor element 1 are alternately changed. Therefore, as shown in FIG. 16A, the rightmost circuit board 3 and the second rightmost circuit board 3′ in the figure are rotationally symmetrical as viewed from above.

In a top layer of the holding plate 41, an adhesive layer (not shown) whose adhesion properties can be changed is formed, and therefore, after a semiconductor device is formed, the holding plate 41 can be detached and removed from the semiconductor device. For example, when the adhesive layer is made of a UV curable adhesive, after a semiconductor device is formed, the holding plate 41 can be removed by irradiating with UV light.

A board frame 42 is formed on the holding plate 41 outside the opposite sides of the circuit board 3 and 3′. The board frame 42 is used to control the arrangements and positions of the circuit boards 3 and 3′. The board frame 42 also can be used to simultaneously attach the circuit boards 3 and 3′ to the holding plate 41.

Next, as shown in FIG. 16B, in the second sub-step of the placing step, semiconductor elements 1 and 1′ in which connection electrodes 2 and 2′ are formed on first main surfaces 1a and 1a′, are formed on the holding plate 41 at predetermined positions with the first main surfaces 1a and 1a′ facing upward. As described above, in this embodiment of FIG. 16, the orientations of the semiconductor elements 1 and 1′ and the circuit boards 3 and 3′ are alternately changed, and therefore, as with the circuit boards 3 and 3′, the semiconductor elements 1 and 1′ in the rightmost column and in the second rightmost column of FIG. 16B are also rotationally symmetrical as viewed from above. Here, as described below with reference to FIG. 17, by devising an arrangement pattern on the semiconductor board during manufacture of the semiconductor element 1, the semiconductor elements 1 and 1′ arranged in columns can be simultaneously placed on the holding plate 41.

The above steps of placing the semiconductor elements 1 and the circuit boards 3 on the holding plate as shown in FIGS. 16A and 16B constitute the placing step. Note that the order in which the semiconductor elements 1 and the circuit boards 3 are placed on the holding plate 41 in the placing step is not limited to the above example. Alternatively, the semiconductor elements 1 may be mounted in the first sub-step, and the circuit boards 3 may be mounted in the second sub-step.

Alternatively, the mounting of a portion of the semiconductor elements 1 and the mounting of a portion of the circuit boards 3 may be performed alternately.

Alternatively, the semiconductor elements 1 and the circuit boards 3 that are previously separately prepared may be simultaneously mounted.

Next, as shown in FIG. 16C, a connecting step is performed in which the connection electrodes 2 and 2′ formed on the first main surfaces 1a and 1a′ of the semiconductor elements 1 and 1′, and the electrode pads 4 and 4′ formed on the first main surface 3a and 3a′ of the circuit boards 3 and 3′ adjacent to the corresponding semiconductor elements 1 and 1′, are connected together by connection wires 6 and 6′. The connecting step can be performed in accordance with a typical wire bonding procedure.

Thereafter, as shown in FIG. 16D, a covering step is performed in which the first main surfaces 1a and 1a′ of the semiconductor elements 1 and 1′, the first main surfaces 3a and 3a′ of the circuit boards 3 and 3′, and the connection wires 6 and 6′ are covered with an encapsulation resin 7. In this case, the encapsulation resin 7 is preferably extended onto the board frame 42 at both end portions thereof so that the first main surfaces 3a and 3a′ of the circuit boards 3 and 3′ are completely covered.

After the encapsulation resin 7 is cured, as shown in FIG. 16E a holding plate removing step of removing the holding plate 41 is performed. The holding plate removing step preferably is performed by changing the adhesion properties of an adhesive layer (not shown) formed on the holding plate 41 as described above, for example.

Thereafter, as shown in FIG. 16F, solder balls 43 are mounted on the external electrodes 5 and 5′ formed on the second main surface 3b and 3b′ of the circuit boards 3 and 3′ when the external electrodes 5 and 5′ need to be connected to an external circuit board (not shown), such as a motherboard etc. If the external electrodes 5 and 5′ do not need to be connected to an external circuit board, this step may, of course, be removed.

Finally, as shown in FIG. 16G, the semiconductor devices 100 in which the semiconductor elements 1 and 1′ and the circuit boards 3 and 3′ are integrated together by the encapsulation resin 7, are separated from each other into individual ones (i.e., singulated) by dicing etc.

Note that in the case where the solder ball mounting step of FIG. 16F is not required, the semiconductor devices still mounted on the holding plate 21 may be separated from each other into individual ones before the holding plate removing step, and the holding plate removing step performed on each individual semiconductor device 100 to remove the semiconductor device 100 from the holding plate 21.

Next, FIG. 17 is a diagram relating to the semiconductor device manufacturing method of this embodiment, showing how the semiconductor elements 1 and 1′ and the circuit boards 3 and 3′ are arranged on the holding plate 41. Note that FIG. 17 shows a state after the connecting step of FIG. 16C is completed, in which the encapsulation resin 7 has not yet been formed. Also, the board frame 42 is provided over the holding plate 41, which is therefore not shown in FIG. 17. Moreover, for the sake of simplicity of the drawing, the external electrodes 5 and 5′ formed on the second main surfaces 3a and 3a′ of the circuit boards 3 and 3′ are not shown.

As shown in FIG. 17, in this embodiment, the semiconductor elements 1 and 1′ and the circuit boards 3 and 3′ (four each of them) are arranged continuously in a direction perpendicular to a direction in which the semiconductor elements and the corresponding circuit boards are adjacent, i.e., the length direction of FIG. 17. Thus, by continuously arranging the multiple semiconductor elements 1 and 1′ in the direction perpendicular to the direction in which the semiconductor element and the circuit board connecting together are adjacent, the semiconductor elements 1 and 1′ manufactured and arranged continuously on the silicon board can be placed along with dummy elements 44 formed at both end portions in the arrangement direction, as a continuous member, on the holding plate 41. With this configuration, the multiple semiconductor elements 1 and 1′ can be mounted simultaneously onto the holding plate 41, whereby the placing step can be significantly simplified, compared to when the individual separate semiconductor elements 1 diced from the semiconductor board are mounted onto the holding plate 41. Moreover, as described above, the multiple circuit boards 3 can be mounted simultaneously onto the holding plate 41 by using the board frame 42. By using these techniques, the semiconductor elements and the circuit boards are simultaneously mounted onto the holding plate 41 (i.e., the placing step is simplified), and after the semiconductor elements and the circuit boards are connected together, the semiconductor devices are simultaneously separated from each other into individual ones by dicing etc., whereby the overall manufacturing process of the semiconductor device of this embodiment can be simplified.

Here, if the orientations of the circuit boards 3 and the semiconductor elements 1 are alternately changed, and the circuit boards 3 and the semiconductor elements 1 provided in the respective columns are symmetrical with respect to a point as described above, two columns of the semiconductor elements 1 that have been simultaneously formed on a wafer can be simultaneously excised and then connected to circuit boards, and thereafter, can be subdivided into individual semiconductor devices.

Note that, of course, the present invention does not necessarily require that the orientations of the circuit board 3 and the semiconductor element 1 are alternately changed.

Also, according to the semiconductor device manufacturing method of this embodiment, as described above, a plurality of combinations of a semiconductor element and a circuit board are arranged on the board frame 42 and then an encapsulation resin is applied, and thereafter, the semiconductor devices are separated from each other by cutting. Therefore, the semiconductor devices can be separated from each other into individual ones, and at the same time, the cut surface (side surface) of the semiconductor element can be exposed to the outside of the semiconductor device without being covered with the encapsulation resin. The number of exposed side surfaces of the semiconductor element can be increased with an increase in the number of times of cutting for separating the semiconductor devices from each other into individual ones. As shown in FIG. 17, when the semiconductor devices are arranged in the length direction and the width direction, i.e., in a matrix and are separated from each other into individual ones, three side surfaces of each semiconductor element can be exposed without being covered with the encapsulation resin.

Also, according to the semiconductor device manufacturing method of this embodiment, the multiple connection wires 6 of the semiconductor devices 100 mounted on the holding plate 41 can have the same direction from the gate opening to the vent opening or from the vent opening to the gate opening of a sealed die. Also, the connection wires 6 can have the same length. Therefore, the flow of the wire can be controlled more easily, whereby the adjacent connection wires 6 can be effectively and reliably prevented from undesirably contacting each other. Because the multiple connection wires 6 have the same orientation, the connection wires 6 can be arranged in a line and simultaneously subjected to wire bonding. This feature also contributes to an improvement in the productivity of the semiconductor device.

As described above, according to the semiconductor device manufacturing method of the present invention described with reference to FIGS. 16 and 17, the semiconductor device of the present invention described in the first embodiment can be easily and efficiently manufactured.

Note that, as shown in FIG. 16D, in the encapsulating step of this embodiment, the gaps 14 between the semiconductor elements 1 and 1′ and the circuit boards 3 and 3′ are filled with the encapsulation resin 7. As described above in the first embodiment, it is possible to appropriately determine whether to fill the gaps 14 between the semiconductor elements 1 and 1′ and the circuit boards 3 and 3′ with the encapsulation resin 7, depending on characteristics required for the semiconductor device 100. When the gaps 14 between the semiconductor elements 1 and 1′ and the circuit boards 3 and 3′ are to be filled with the encapsulation resin 7, it is preferable to perform the placing step while adjusting the size of the gap based on the size of a filler (resin material) used as the encapsulation resin 7.

Specifically, for example, when the filler of the encapsulation resin 7 has a size distribution up to about 50 μm, then if, in the placing step, the semiconductor elements 1 and 1′ and the circuit boards 3 and 3′ are arranged on the holding plate 41 so that the gaps therebetween are smaller than or equal to 50 μm, the filler of the encapsulation resin 7 sticks, covering the gaps, so that the gaps are not filled with the encapsulation resin 7. In this case, if the gap is set to be greater than or equal to 50 μm, the gap can be filled with the encapsulation resin. Therefore, the gap between the semiconductor element and the circuit board is determined appropriately based on whether or not the gap between the semiconductor element and the circuit board is to be filled with the encapsulation resin, and the size distribution of the filler included in the encapsulation resin.

In the first through fourth embodiments of the present invention, an example has been described in which the connection electrode of the semiconductor element and the electrode pad of the circuit board are connected together via a connection wire that is a metal wire. However, in the present invention, the connector connecting the connection electrode of the semiconductor device and the electrode pad of the circuit board together is not limited to a metal wire, and the concept of the connector encompasses beam leads, and connection wires used in other techniques. In addition to connection wires, various other connectors can be used, including electrically conductive paste, film boards, interconnection boards in which an interconnect pattern is formed on a rigid board similar to a circuit board, connection patterns formed by other printing techniques, etc.

FIG. 18 shows a configuration of a semiconductor device 100A in which a film board 72 on a surface of which a plurality of bands of electrically conductive paste 71 are provided is used as a connector instead of the metal wire (connector) 6 in the semiconductor device 100 of the first embodiment of the present invention of FIG. 1. FIG. 18A is a plan view of the configuration. FIG. 18B is a cross-sectional view of the configuration. Note that the semiconductor device 100A of FIG. 18 is different from the semiconductor device 100 of FIG. 1 only in the connector connecting the connection electrode of the semiconductor device and the electrode pad of the circuit board together. Therefore, the other parts are indicated by the same reference characters and will not be described in detail.

As shown in FIG. 18, in the semiconductor device 100A having the different connector, in order to connect the connection electrodes 2 of the semiconductor element 1 and the respective corresponding electrode pads 4 of the circuit board 3 together, the film board 72 on a surface of which the electrically conductive paste 71 bands having a width that is the same as or slightly narrower than widths of the connection electrode 2 and the electrode pad 4, are formed, by printing, at a pitch similar to intervals at which the connection electrodes 2 and the electrode pads 4 are arranged, is arranged so that the surface on which the electrically conductive paste 71 is printed faces the first main surfaces 1a and 3a of the semiconductor element 1 and the circuit board 3. With this configuration, the connection electrodes 2 and the electrode pads 4 corresponding to each other simultaneously can be connected together, whereby the connecting step of the semiconductor element 1 and the circuit board 3 can be simplified.

Note that, in FIG. 18, the encapsulation resin 7 is formed to cover the film board 72 on which the electrically conductive paste 71 is applied. Because the electrically conductive paste 71 is covered by the film board 72, it is no longer necessary to avoid a short circuit between the connector and the outside of the semiconductor device. This is not the case when wire bonding is performed using a metal wire or when only the electrically conductive paste 71 is used for connection.

Therefore, the encapsulation resin 7 does not necessarily need to be formed on the film board 72. If the semiconductor device 100A has sufficient strength, the encapsulation resin 7 may be formed separately on the first main surface 1a of the semiconductor element 1 and on the first main surface 3a of the circuit board 3. In particular, when a board made of a resin having a predetermined thickness and physical strength is used as the connector, the necessity of an encapsulation resin covering an upper portion of the connector further is reduced.

### Other Semiconductor Devices

Here, another semiconductor device 600 to which the concept of the semiconductor device of the present invention is applied will be described with reference to FIG. 19.

FIG. 19 is a diagram showing a configuration of the semiconductor device 600. FIG. 19A is a plan view of the configuration as viewed from above a first main surface of the semiconductor device 600. FIG. 19B is a cross-sectional view of the configuration taken along arrowed line H-H′ of FIG. 19A.

The semiconductor device 600 of FIG. 19 is different from the semiconductor devices 100, 200, 300, 400, and 500 of the present invention described above in the embodiments of the present invention in that a first semiconductor element 1 and a second semiconductor element 61 are arranged side by side so that first main surfaces 1a and 61a thereof face in the same direction and side surfaces 1c1 and 61c1 thereof face each other. In addition, connection electrodes 2 formed on the first main surface 1a of the first semiconductor element 1 and connection electrodes 62 formed on the first main surface 61a of the second semiconductor element 61 are connected together by connection wires 65 made of a metal.

On a second main surface 61b of the second semiconductor element 61, external electrodes 63 for connecting the second semiconductor element 61 to an external board (not shown) are formed in length and width directions, i.e., in a matrix. The external electrodes 63 of the second semiconductor element 61 are connected to the connection electrodes 62 formed on the first main surface 61a and a semiconductor integrated circuit (not shown) by through interconnects 64 formed in the second semiconductor element 61.

An encapsulation resin 66 made of epoxy resin etc. is formed to cover the first the first main surface 1a of the semiconductor element 1, the first main surface 61a of the second semiconductor element 61, and the connection wires 65 for providing electrical conduction between the connection electrodes 2 and the connection electrodes 62.

In some semiconductor devices, a plurality of semiconductor elements are connected by bumps while being stacked together, and the resulting multilayer structure is mounted on a circuit board (multilayer bump connection). In this case, the semiconductor elements are stacked together, and therefore, it is difficult to provide satisfactory heat dissipation characteristics to semiconductor elements that are not located at the outermost surface. In this case, by applying the technical aspect of the present invention that the heat dissipation characteristics of the semiconductor element can be improved when the semiconductor element and the circuit board are connected together, the heat dissipation characteristics of a large number of semiconductor elements can be improved while the function of the multilayer connection semiconductor device is ensured.

Although the circuit board in the semiconductor device 600 of FIG. 19 has not bee mentioned, the circuit board may be formed lateral to the semiconductor device 600, or may be arranged to face the second main surface 61b of the second semiconductor element 61. If two or more semiconductor elements are used, a plurality of semiconductor elements for which satisfactory heat dissipation characteristics should be ensured can, of course, be successively arranged laterally.

In order to improve the heat dissipation characteristics of the semiconductor element, various means for improving the heat dissipation characteristics described above in the embodiments of the present invention, such as connecting a heat sink fm and the like, of course are applicable to the semiconductor device 600 of FIG. 19.

Moreover, similar to the semiconductor devices of the embodiments of the present invention described above, as the connector electrically connecting the two semiconductor elements 1 and 61 together, other connectors such as electrically conductive paste etc. can be used in addition to the metal connection wire 65.

### INDUSTRIAL APPLICABILITY

The semiconductor device of the present invention, the semiconductor package in which the semiconductor device is mounted, and the method for manufacturing the semiconductor device, can achieve high heat dissipation characteristics for the semiconductor element and high productivity for the semiconductor device, and therefore, are industrially useful as semiconductor devices for use in various electronic apparatuses, and semiconductor packages.

1. A semiconductor device, comprising:
a first semiconductor element having a first main surface on which a connection electrode is disposed, a second main surface opposite to the first main surface, and a plurality of side surfaces; and
a first circuit board having a first main surface on which an electrode pad is disposed, a second main surface opposite to the first main surface, and a plurality of side surfaces,
wherein the first main surfaces of the first semiconductor element and the first circuit board face in the same direction and the side surfaces of the first semiconductor element and the first circuit board face each other, the connection electrode and the electrode pad are connected together, and
the first main surfaces of the first semiconductor element and the first circuit board are covered with an encapsulation resin.

2. The semiconductor device according to claim 1, wherein
at least one of the side surfaces of the first semiconductor element is exposed.

3. The semiconductor device according to claim 1, further comprising a second circuit board having a plurality of side surfaces,
wherein the side surface of the first circuit board substantially faces the side surface of the first semiconductor element, and
the side surface of the second circuit board substantially faces the other side surface of the first semiconductor element.

4. The semiconductor device according to claim 1, further comprising a second semiconductor element having a plurality of side surfaces,
wherein the side surface of the first semiconductor element substantially faces the side surface of the first circuit board, and
the side surface of the second semiconductor element substantially faces the other side surface of the first circuit board.

5. The semiconductor device according to claim 1, wherein
an integrated circuit is disposed on the second main surface of the first semiconductor element and is connected to the connection electrode disposed on the first main surface of the first semiconductor element by a connection interconnect penetrating through the first semiconductor element.

6. A semiconductor package, wherein
the semiconductor device according to claim 1 is mounted on an external circuit board, and
an external electrode disposed on the second main surface of the first circuit board in the semiconductor device is connected to an electrode terminal disposed on a mounting surface of the external circuit board on which the semiconductor device is mounted.

7. The semiconductor package according to claim 6, wherein
the first semiconductor element in the semiconductor device protrudes laterally from the external circuit board.

8. The semiconductor package according to claim 6, wherein
at least one of the side surfaces and the second main surface of the first semiconductor element in the semiconductor device contacts heat dissipation portion.

9. The semiconductor package according to claim 6, wherein
a gap is formed between the first semiconductor element in the semiconductor device and the external circuit board.

10. The semiconductor package according to claim 9, wherein
the gap between the first semiconductor element and the external circuit board is filled with an underfill.

11. The semiconductor device according to claim 1, wherein
at least one of the side surfaces of the first semiconductor element and a side surface of the encapsulation resin lie in a substantially same plane.

12. The semiconductor device according to claim 11, wherein
at least one of the side surfaces of the first circuit board and a side surface of the encapsulation resin lie in a substantially same plane.

13. The semiconductor device according to claim 1, wherein
at least one of the side surfaces of the first circuit board and a side surface of the encapsulation resin lie in a substantially same plane.

14. The semiconductor device according to claim 1, wherein
the second main surfaces of the first semiconductor element and the first circuit board are exposed from the encapsulation resin.

15. The semiconductor device according to claim 1, wherein
the first main surface of the first semiconductor element is substantially as high as the first main surface of the first circuit board.
